(19) United States
(12) Patent Application Publication
(10) Pub. No.: US 2011/0284971 A1
(43) Pub. Date: Nov. 24, 2011

(54) SEMICONDUCTOR DEVICE AND MANUFACTURING METHOD THEREOF

(75) Inventors: Shinsuke SAKASHITA, Kanagawa (JP); Takaaki Kawahara, Kanagawa (JP); Masaru Kadoshima, Kanagawa (JP); Masao Inoue, Kanagawa (JP); Hiroshi Umeda, Kanagawa (JP)

(73) Assignee: Renesas Electronics Corporation

(21) Appl. No.: 13/109,736

(22) Filed: May 17, 2011

(30) Foreign Application Priority Data
May 24, 2010 (JP) 2010-118368

(51) Int. Cl. H01L 27/092; H01L 21/28

(52) U.S. Cl. 257/369; 438/591; 257/E27.062; 257/E21.19

(57) ABSTRACT

There are provided a semiconductor device in which the threshold voltage of a p-channel field effect transistor is reliably controlled to allow a desired characteristic to be obtained, and a manufacturing method thereof. As a heat treatment performed at a temperature of about 700 to 900° C. proceeds, in an element formation region, aluminum (Al) in an aluminum (Al) film is diffused into a hafnium oxynitride (HfON) film, and thereby added as an element to the hafnium oxynitride (HfON) film. In addition, aluminum (Al) and titanium (Ti) in a hard mask formed of a titanium aluminum nitride (TiAlN) film are diffused into the hafnium oxynitride (HfON) film, and thereby added as elements to the hafnium oxynitride (HfON) film.

### CROSS-REFERENCE TO RELATED APPLICATIONS

The disclosure of Japanese Patent Application No. 2010-118368 filed on May 24, 2010 including the specification, drawings and abstract is incorporated herein by reference in its entirety.

### BACKGROUND

The present invention relates to a semiconductor device and a manufacturing method thereof, and particularly to a semiconductor device including complementary field effect transistors and a manufacturing method thereof.

There is a semiconductor device called a SOC (System On Chip) in which a plurality of logic circuits, memory cells, and the like are mounted on one chip. In a semiconductor device of this type, as a structure of the gate electrode of a field effect transistor such as a MOS (Metal Oxide Semiconductor) transistor, a structure (gate stack structure) has been conventionally used in which a polysilicon film is stacked over a silicon oxynitride film.

In recent years, to reduce a gate leakage current due to a reduced thickness of a silicon oxynitride film (gate insulating film) resulting from the scaling down of a semiconductor device and eliminate a parasitic capacitance between a polysilicon film and the gate insulating film due to the depletion of the polysilicon film, as the gate stack structure, a structure (Hk metal gate structure) in which a metal film is stacked over a high-dielectric-constant (High-k) gate insulating film having a dielectric constant higher than that of a silicon oxynitride film has been considered to be indispensable.

However, a field effect transistor in which a High-k film is used properly as a gate insulating film has the problem of an increased threshold voltage (Vth) thereof. To reduce power consumption, it is required to reduce the threshold voltage. To reduce the threshold voltage, it is necessary to set the work function (work function n) of the gate electrode of an n-channel field effect transistor and the work function (work function p) of the gate electrode of a p-channel field effect transistor at different values. It is assumed here that the work function n is, e.g., 4.1 eV and the work function p is, e.g., 5.1 eV. As a result, it is needed to properly use High-k films and metal films of different materials for the n-channel field effect transistor and the p-channel field effect transistor, and vigorous study and development has been conducted.

For the n-channel field effect transistor, a technique has been developed which stacks, e.g., a LaO film, a YO film, a MgO film, or the like over the High-k film, and causes the diffusion (mixing) of lanthanum (La), yttrium (Y), magnesium (Mg), or the like into the High-k film to thereby control the work function n. On the other hand, for the p-channel field effect transistor, a technique has been developed which stacks, e.g., an AlO film, a TiO film, a TaO film, or the like over the High-k film, and causes the diffusion (mixing) of aluminum (Al), titanium (Ti), tantalum (Ta), or the like into the High-k film to thereby control the work function p.

Examples of a document which discloses a gate electrode of this type include Non-Patent Documents 1 and 2.

### RELATED ART DOCUMENTS

### Non-Patent Documents

### [Non-Patent Document 1]

T. Schram et al., “Novel Process To Pattern selectively Dual Dielectric Capping Layers Using Soft-Mask Only”, 2008 Symposium on VLSI Technology Digest of Technical Papers pp. 44-45. 2008.

### [Non-Patent Document 2]

S. C. Song et al., “Highly manufacturable 45 nm LSTP CMOSFETs Using Novel Dual High-k and Dual Metal Gate CMOS Integration”, 2006 Symposium on VLSI Technology Digest of Technical Papers pp. 16-17. 2006.

### SUMMARY

The present invention has been achieved as part of the research and development of the Hk metal gate structure described above, and an object thereof is to provide a semiconductor device in which the threshold voltage of a p-channel field effect transistor, in particular, is reliably controlled to allow a desired characteristic to be obtained. Another object of the present invention is to provide a method of manufacturing such a semiconductor device.

A semiconductor device according to the present invention is a semiconductor device including complementary field effect transistors, and includes a first element formation region for a p-channel field effect transistor, a second element formation region for an n-channel field effect transistor, a first gate insulating film, a first gate electrode, a second gate insulating film, and a second gate electrode. The first element formation region and the second element formation region are formed in a main surface of a semiconductor substrate. The first gate insulating film is formed so as to come in contact with a surface of the first element formation region. The first gate electrode is formed so as to come in contact with a surface of the first gate insulating film. The second gate insulating film is formed so as to come in contact with a surface of the second element formation region. The second gate electrode is formed so as to come in contact with a surface of the second gate insulating film. The first gate insulating film is a hafnium aluminum titanium oxynitride (HfAlTiON) film obtained by adding aluminum (Al) and titanium (Ti) as elements to a hafnium oxynitride (HfON) film. The second gate insulating film is a hafnium lanthanum oxynitride (HfLaON) film obtained by adding lanthanum (La) as an element to the hafnium oxynitride (HfON) film.

A method of manufacturing a semiconductor device according to the present invention is a method of manufacturing a semiconductor device including complementary field effect transistors, and includes the following steps. In a main surface of a semiconductor substrate, a first element formation region for a p-channel field effect transistor and a second element formation region for an n-channel field effect transistor are formed. A hafnium oxynitride (HfON) film is formed so as to come in contact with respective surfaces of the first element formation region and the second element formation region. A first-predetermined-element containing film containing aluminum (Al) as a predetermined element for controlling a threshold voltage of the p-channel field effect transistor is formed so as to come in contact with a surface of the hafnium oxynitride (HfON) film. A hard mask containing aluminum (Al) as a predetermined element for controlling the threshold voltage of the p-channel field effect transistor is formed into a configuration in which the hard mask exposes a portion of the first-predetermined-element containing film located in the second element formation region, and covers a portion of the first-predetermined-element containing film located in the first element formation region. Using the hard mask as a mask, processing is performed to expose a portion of the hafnium oxynitride (HfON) film located in the second element formation region. A second-predetermined-element containing film containing lanthanum (La) as a predetermined element for controlling a threshold voltage of the n-channel field effect transistor is formed so as to cover the portion of the hafnium oxynitride (HfON) film exposed in the second element formation region and the hard mask. A heat treatment is performed so as to add aluminum (Al) from the first-predetermined-element containing film to the hafnium oxynitride (HfON) film to form a first insulating film in the first element formation region, and add lanthanum (La) from the second-predetermined-element containing film to the hafnium oxynitride (HfON) film to form a second insulating film in the second element formation region. A predetermined metal film is formed so as to come in contact with respective surfaces of the first insulating film and the second insulating film. A polysilicon film is formed so as to come in contact with a surface of the metal film. Predetermined patterning is performed on the polysilicon film, the metal film, the first insulating film, and the second insulating film to form a first gate electrode over the surface of the first element formation region via a first gate insulating film in the first element formation region, and form a second gate electrode over the surface of the second element formation region via a second gate insulating film in the second element formation region.

Another method of manufacturing a semiconductor device according to the present invention is a method of manufacturing a semiconductor device including complementary field effect transistors, and includes the following steps. In a main surface of a semiconductor substrate, a first element formation region for a p-channel field effect transistor and a second element formation region for an n-channel field effect transistor are formed. A hafnium oxynitride (HfON) film is formed so as to come in contact with respective surfaces of the first element formation region and the second element formation region. A hard mask containing aluminum (Al) as a predetermined element for controlling a threshold voltage of the p-channel field effect transistor is formed into a configuration in which the hard mask exposes a portion of the hafnium oxynitride (HfON) film located in the second element formation region, and covers a portion of the hafnium oxynitride (HfON) film located in the first element formation region. A predetermined-element containing film containing lanthanum (La) as a predetermined element for controlling a threshold voltage of the n-channel field effect transistor is formed so as to cover the portion of the hafnium oxynitride (HfON) film exposed in the second element formation region and the hard mask. A heat treatment is performed so as to add aluminum (Al) from the hard mask to the hafnium oxynitride (HfON) film to form a first insulating film in the first element formation region, and add lanthanum (La) from the predetermined-element containing film to the hafnium oxynitride (HfON) film to form a second insulating film in the second element formation region. A predetermined metal film is formed so as to come in contact with respective surfaces of the first insulating film and the second insulating film. A polysilicon film is formed so as to come in contact with a surface of the metal film. Predetermined patterning is performed on the polysilicon film, the metal film, the first insulating film, and the second insulating film to form a first gate electrode over the surface of the first element formation region via a first gate insulating film in the first element formation region, and form a second gate electrode over the surface of the second element formation region via a second gate insulating film in the second element formation region.

Still another method of manufacturing a semiconductor device according to the present invention is a method of manufacturing a semiconductor device including complementary field effect transistors, and includes the following steps. In a main surface of a semiconductor substrate, a first element formation region for a p-channel field effect transistor and a second element formation region for an n-channel field effect transistor are formed. A hafnium oxynitride (HfON) film is formed so as to come in contact with respective surfaces of the first element formation region and the second element formation region. A first-predetermined-element containing film containing aluminum (Al) as a predetermined element for controlling a threshold voltage of the p-channel field effect transistor is formed so as to come in contact with a surface of the hafnium oxynitride (HfON) film. A hard mask formed of a titanium nitride (TiN) film containing titanium (Ti) and nitrogen (N) as elements at a predetermined composition ratio R is formed so as to cover a portion of the first-predetermined-element containing film located in the first element formation region. Using the hard mask as a mask, processing is performed to expose a portion of the hafnium oxynitride (HfON) film located in the second element formation region. A second-predetermined-element containing film containing lanthanum (La) as a predetermined element for controlling a threshold voltage of the n-channel field effect transistor is formed so as to cover the portion of the hafnium oxynitride (HfON) film exposed in the second element formation region and the hard mask. A heat treatment is performed so as to add aluminum (Al) from the first-predetermined-element containing film to the hafnium oxynitride (HfON) film to form a first insulating film in the first element formation region, and add lanthanum (La) from the second-predetermined-element containing film to the hafnium oxynitride (HfON) film to form a second insulating film in the second element formation region. A predetermined metal film is formed so as to come in contact with respective surfaces of the first insulating film and the second insulating film. A polysilicon film is formed so as to come in contact with a surface of the metal film. Predetermined patterning is performed on the polysilicon film, the metal film, the first insulating film, and the second insulating film to form a first gate electrode over the surface of the first element formation region via a first gate insulating film in the first element formation region, and form a second gate electrode over the surface of the second element formation region via a second gate insulating film in the second element formation region. In the step of forming the hard mask, the hard mask is formed such that the composition ratio R satisfies 1≦R≦1.1.

With the semiconductor device according to the present invention, aluminum (Al) added to the hafnium oxynitride (HfON) film allows the threshold voltage of the p-channel field effect transistor to be reliably controlled. In addition, the equivalent oxide thickness of the first gate insulating film that has been increased by the addition of aluminum (Al) can be reduced by adding titanium (Ti) thereto. Therefore, a desired characteristic can be obtained from the p-channel field effect transistor.

In accordance with the method of manufacturing the semiconductor device according to the present invention, the hard mask containing aluminum (Al) as an element is used properly to suppress the diffusion of aluminum (Al) from the first-predetermined-element containing film into the hard mask. Thus, the diffusion of aluminum into the hard mask is suppressed, and accordingly aluminum (Al) in the first-predetermined-element containing film is sufficiently diffused toward the hafnium oxynitride (HfON) film. Aluminum (Al) in the hard mask is also diffused into the hafnium oxynitride (HfON) film through the first-predetermined-element containing film. As a result, the threshold voltage of the p-channel field effect transistor can be reliably controlled.

In accordance with the other method of manufacturing the semiconductor device according to the present invention, the hard mask containing aluminum (Al) as an element is used properly to allow aluminum (Al) in the hard mask to be diffused into the hafnium oxynitride (HfON) film without additionally forming an aluminum (Al) film. As a result, the threshold voltage of the p-channel field effect transistor can be reliably controlled.

In accordance with the still other method of manufacturing the semiconductor device according to the present invention, aluminum (Al) in the aluminum (Al) film is added to the hafnium oxynitride (HfON) film, while the hard mask formed of the titanium nitride (TiN) film in which the composition ratio R (N/Ti) is in a predetermined range (1≦R≦1.1) is used properly to suppress the amount of nitrogen (N) diffused from the hard mask toward the hafnium oxynitride (HfON) film. This allows reliable control of the threshold voltage of the p-channel field effect transistor.

### BRIEF DESCRIPTION OF THE DRAWINGS

FIG. 1 is a cross-sectional view showing a step of a method of manufacturing a semiconductor device according to a first embodiment of the present invention;

FIG. 2 is a cross-sectional view showing a step performed after the step shown in FIG. 1 in the first embodiment;

FIG. 3 is a cross-sectional view showing a step performed after the step shown in FIG. 2 in the first embodiment;

FIG. 4 is a cross-sectional view showing a step performed after the step shown in FIG. 3 in the first embodiment;

FIG. 5 is a cross-sectional view showing a step performed after the step shown in FIG. 4 in the first embodiment;

FIG. 6 is a cross-sectional view showing a step performed after the step shown in FIG. 5 in the first embodiment;

FIG. 7 is a cross-sectional view showing a step performed after the step shown in FIG. 6 in the first embodiment;

FIG. 8 is a cross-sectional view showing a step performed after the step shown in FIG. 7 in the first embodiment;

FIG. 9 is a cross-sectional view showing a step performed after the step shown in FIG. 8 in the first embodiment;

FIG. 10 is a cross-sectional view showing a step performed after the step shown in FIG. 9 in the first embodiment;

FIG. 11 is a cross-sectional view showing a step performed after the step shown in FIG. 10 in the first embodiment;

FIG. 12 is a cross-sectional view showing a step performed after the step shown in FIG. 11 in the first embodiment;

FIG. 13 is a cross-sectional view showing a step performed after the step shown in FIG. 12 in the first embodiment;

FIG. 14 is a cross-sectional view showing a step performed after the step shown in FIG. 13 in the first embodiment;

FIG. 15 is a cross-sectional view showing the diffusion of an element for controlling a threshold voltage in a semiconductor device according to a comparative example;

FIG. 16 is a cross-sectional view showing the diffusion of an element for controlling the threshold voltage of a p-channel field effect transistor in the first embodiment;

FIG. 17 is a cross-sectional view schematically showing a structure of gate insulating films and gate electrodes in complementary field effect transistors in the first embodiment;

FIG. 18 is a cross-sectional view showing a step of a method of manufacturing a semiconductor device according to a second embodiment of the present invention;

FIG. 19 is a cross-sectional view showing a step performed after the step shown in FIG. 18 in the second embodiment;

FIG. 20 is a cross-sectional view showing a step performed after the step shown in FIG. 19 in the second embodiment;

FIG. 21 is a cross-sectional view showing a step performed after the step shown in FIG. 20 in the second embodiment;

FIG. 22 is a cross-sectional view showing a step performed after the step shown in FIG. 21 in the second embodiment;

FIG. 23 is a cross-sectional view showing a step performed after the step shown in FIG. 22 in the second embodiment;

FIG. 24 is a cross-sectional view showing a step performed after the step shown in FIG. 23 in the second embodiment;

FIG. 25 is a cross-sectional view showing a step performed after the step shown in FIG. 24 in the second embodiment;

FIG. 26 is a cross-sectional view showing a step performed after the step shown in FIG. 25 in the second embodiment;

FIG. 27 is a cross-sectional view showing a step performed after the step shown in FIG. 26 in the second embodiment;

FIG. 28 is a cross-sectional view showing a step performed after the step shown in FIG. 27 in the second embodiment;

FIG. 29 is a cross-sectional view showing the diffusion of an element for controlling the threshold voltage of a p-channel field effect transistor in the second embodiment;

FIG. 30 is a cross-sectional view schematically showing a structure of gate insulating films and gate electrodes in complementary field effect transistors in the second embodiment;

FIG. 31 is a cross-sectional view showing a step of a method of manufacturing a semiconductor device according to a third embodiment of the present invention;

FIG. 32 is a cross-sectional view showing a step performed after the step shown in FIG. 31 in the third embodiment;

FIG. 33 is a cross-sectional view showing a step performed after the step shown in FIG. 32 in the third embodiment;

FIG. 34 is a cross-sectional view showing a step performed after the step shown in FIG. 33 in the third embodiment;

FIG. 35 is a cross-sectional view showing a step performed after the step shown in FIG. 34 in the third embodiment;

FIG. 36 is a cross-sectional view showing a step performed after the step shown in FIG. 35 in the third embodiment;

FIG. 37 is a cross-sectional view showing a step performed after the step shown in FIG. 36 in the third embodiment;

FIG. 38 is a cross-sectional view showing a step performed after the step shown in FIG. 37 in the third embodiment;

FIG. 39 is a cross-sectional view showing a step performed after the step shown in FIG. 38 in the third embodiment;

FIG. 40 is a cross-sectional view showing a step performed after the step shown in FIG. 39 in the third embodiment;

FIG. 41 is a cross-sectional view showing a step performed after the step shown in FIG. 40 in the third embodiment;

FIG. 42 is a cross-sectional view showing the diffusion of an element for controlling the threshold voltage of a p-channel field effect transistor in the third embodiment;

FIG. 43 is a cross-sectional view schematically showing a structure of gate insulating films and gate electrodes in complementary field effect transistors in the third embodiment;

FIG. 44 is a cross-sectional view showing a step of a method of manufacturing a semiconductor device according to a fourth embodiment of the present invention;

FIG. 45 is a cross-sectional view showing a step performed after the step shown in FIG. 44 in the fourth embodiment;

FIG. 46 is a cross-sectional view showing a step performed after the step shown in FIG. 45 in the fourth embodiment;

FIG. 47 is a cross-sectional view showing a step performed after the step shown in FIG. 46 in the fourth embodiment;

FIG. 48 is a cross-sectional view showing a step performed after the step shown in FIG. 47 in the fourth embodiment;

FIG. 49 is a cross-sectional view showing a step performed after the step shown in FIG. 48 in the fourth embodiment;

FIG. 50 is a cross-sectional view showing a step performed after the step shown in FIG. 49 in the fourth embodiment;

FIG. 51 is a cross-sectional view showing a step performed after the step shown in FIG. 50 in the fourth embodiment;

FIG. 52 is a cross-sectional view showing a step performed after the step shown in FIG. 51 in the fourth embodiment;

FIG. 53 is a cross-sectional view showing a step performed after the step shown in FIG. 52 in the fourth embodiment;

FIG. 54 is a cross-sectional view showing a step performed after the step shown in FIG. 53 in the fourth embodiment;

FIG. 55 is a graph showing a relationship between the composition ratio of nitrogen to titanium in a hard mask and a work function in the fourth embodiment;

FIG. 56 is a cross-sectional view showing the diffusion of an element for controlling the threshold voltage of a p-channel field effect transistor in the fourth embodiment; and

FIG. 57 is a cross-sectional view schematically showing a structure of gate insulating films and gate electrodes in complementary field effect transistors in the fourth embodiment.

### DETAILED DESCRIPTION

### First Embodiment

Here, a semiconductor device will be described in which an aluminum (Al) film is used properly as a film containing an element for controlling the threshold voltage of a p-channel field effect transistor. First, as shown in FIG. 1, in a predetermined region of a surface of a semiconductor substrate 1, by, for example, a STI (Shallow Trench Isolation) method or the like, an isolation insulating film 2 defining element formation regions is formed. Then, in an element formation region RP in which a p-channel field effect transistor is to be formed, n-type impurity ions of, e.g., phosphorus (P), arsenic (As), or the like are implanted to form an n-type well 3. On the other hand, in an element formation region RN in which an n-channel field effect transistor is to be formed, p-type impurity ions of, e.g., boron (B) or the like are implanted to form a p-type well 4.

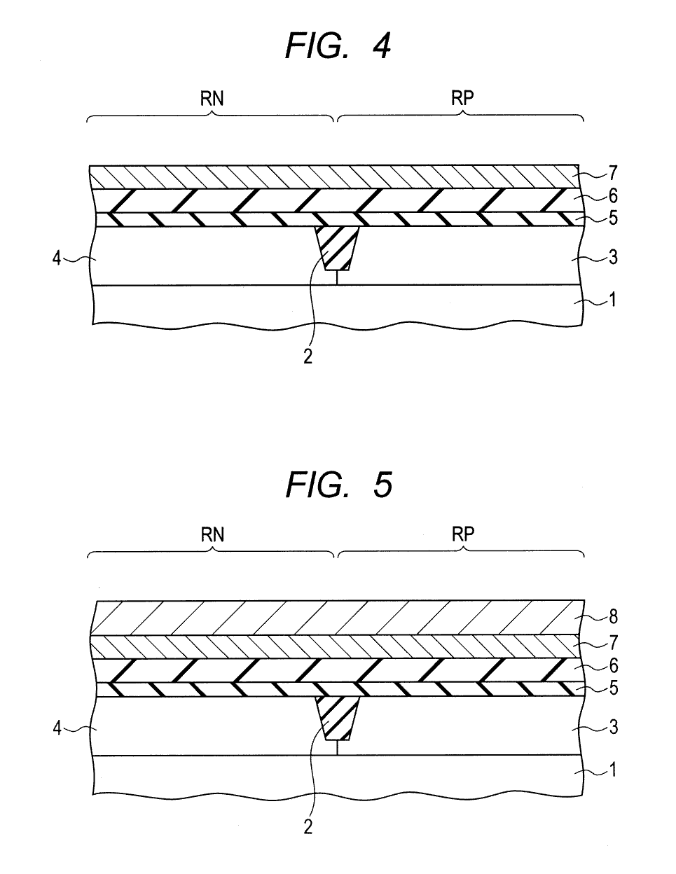

Next, an interface layer (Inter Layer) 5 is formed of a silicon oxide film by, e.g., a RTA (Rapid Thermal Annealing) process so as to come in contact with the respective surfaces of the n-type well 3 and the p-type well 4. Then, as shown in FIG. 3, a hafnium oxynitride (HfON) film 6 is formed as a hafnium-based High-k film. Then, as shown in FIG. 4, as a film containing an element for controlling the threshold voltage of the p-type field effect transistor, an aluminum (Al) film 7 having a thickness of about 0.5 nm is formed so as to come in contact with the surface of the hafnium oxynitride (HfON) film 6.

Next, as shown in FIG. 5, a titanium aluminum nitride (TiAlN) film 8 having a thickness of about 10 nm is formed so as to come in contact with the surface of the aluminum (Al) film 7. The titanium aluminum nitride (TiAlN) film 8 serves as a hard mask when the respective gate insulating films of the p-channel field effect transistor and the n-channel MOS transistor are formed, and contains aluminum (Al) as an element for controlling the threshold voltage of the p-channel field effect transistor. Note that, as necessary, the aluminum (Al) film 7 and the titanium aluminum nitride (TiAlN) film 8 are preferably formed thoroughly in a predetermined vacuum processing chamber.

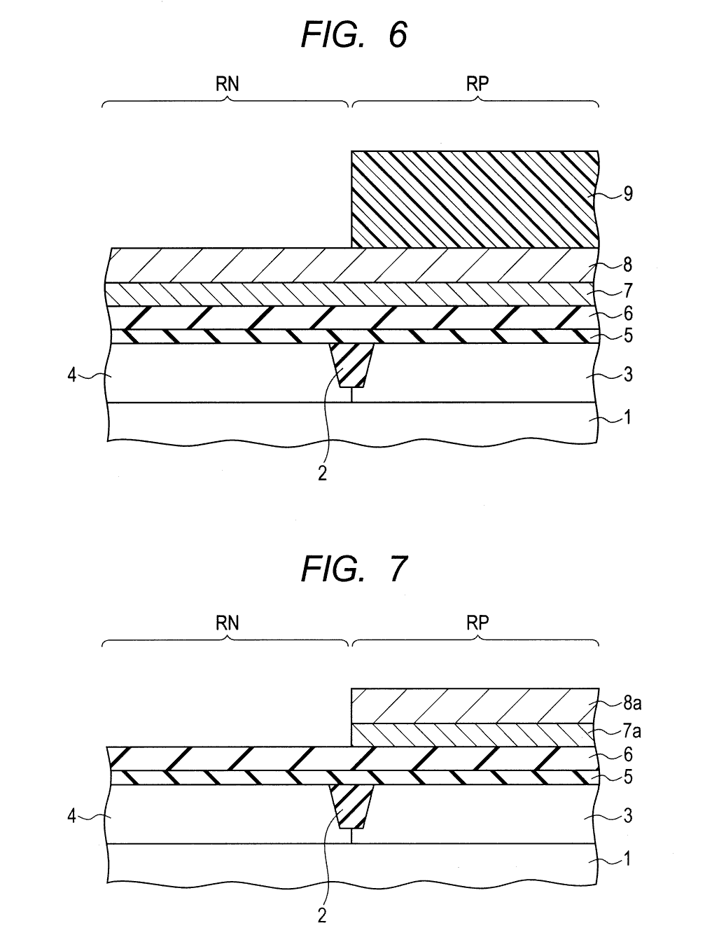

Next, as shown in FIG. 6, a resist mask 9 covering the element formation region RP and exposing the element formation region RN is formed. Then, using the resist mask 9 as an etching mask, e.g., a wet etching treatment is performed to remove the portion of the titanium aluminum nitride (TiAlN) film 8 exposed in the element formation region RP, and expose the surface of the hafnium oxynitride (HfON) film 6. At this time, by using a chemical solution called SPM (Sulfuric acid Hydrogen Peroxide Mix), which is a mixture of a sulfuric acid (H₂SO₄) and aqueous hydrogen peroxide (H₂O₂), it is possible to substantially remove only the portion of the titanium aluminum nitride (TiAlN) film 8 without etching the surface of the hafnium oxynitride film (HfON) film 6. As necessary, it may also be possible to add a wet etching step of removing the portion of the aluminum (Al) film 7 located in the element formation region RN. Thereafter, by removing the resist mask 9, as shown in FIG. 7, a hard mask 8a covering the element formation region RP is formed while, in the element formation region RN, the surface of the hafnium oxynitride (HfON) film 6 is exposed.

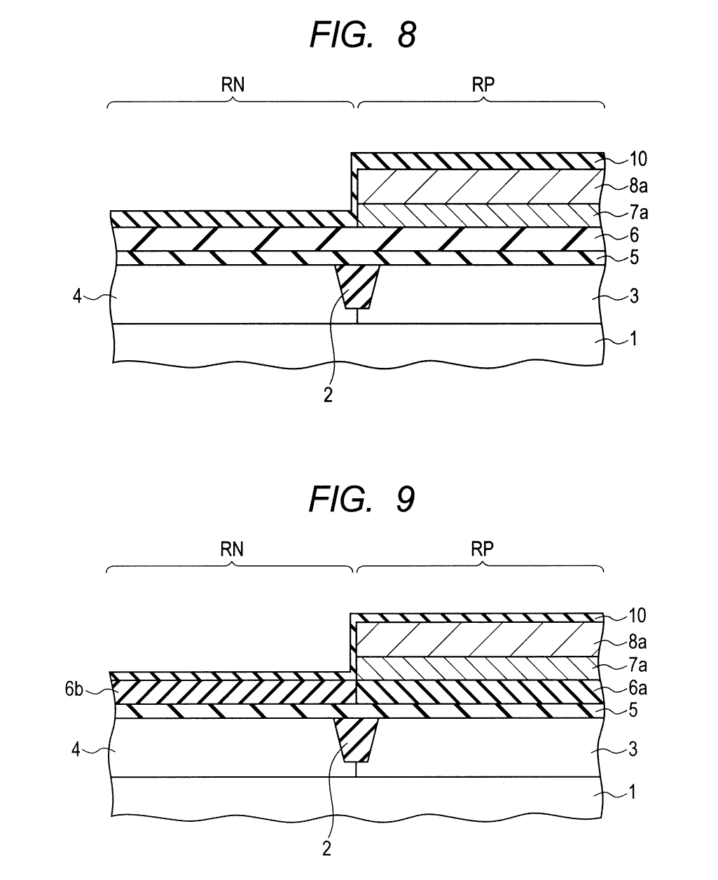

Next, as shown in FIG. 8, a lanthanum oxide (LaO) film 10 having a thickness of about 0.5 nm is formed so as to cover the hafnium oxynitride (HfON) film 6 exposed in the element formation region RN and the hard mask 8a located in the element formation region RP. The lanthanum oxide (LaO) film 10 contains lanthanum (La) as an element for controlling the threshold voltage of the n-channel field effect transistor.

Next, as shown in FIG. 9, a heat treatment is performed at a temperature of about 700 to 900° C. As the heat treatment proceeds, in the element formation region RN, lanthanum (La) or lanthanum oxide (LaO) in the lanthanum oxide (LaO) film 10 is diffused into the hafnium oxynitride (HfON) film 6, and thereby added as an element to the hafnium oxynitride (HfON) film 6 to form a hafnium lanthanum oxynitride (HfLaON) film 6b.

On the other hand, in the element formation region RP, aluminum (Al) in an aluminum (Al) film 7a is diffused into the hafnium oxynitride (HfON) film 6, and thereby added as an element to the hafnium oxynitride (HfON) film 6. In addition, aluminum (Al) and titanium (Ti) in the hard mask 8a formed of the titanium aluminum nitride (TiAlN) film are diffused into the hafnium oxynitride (HfON) film 6, and thereby added as elements to the hafnium oxynitride (HfON) film 6.

Note that, at this time, between the lanthanum oxide (LaO) film 10 and the hafnium oxynitride (HfON) film 6, the hard mask 8a formed of the titanium aluminum nitride (TiAlN) film is formed, and therefore lanthanum (La) is prevented from being diffused into the hafnium oxynitride (HfON) film 6. The diffusion of the elements resulting from the heat treatment will be described later in detail. Thus, in the element formation region RP, aluminum (Al) and titanium (Ti) are added as elements to the hafnium oxynitride (HfON) film 6 to form a hafnium aluminum titanium oxynitride (HfAlTiON) film 6a.

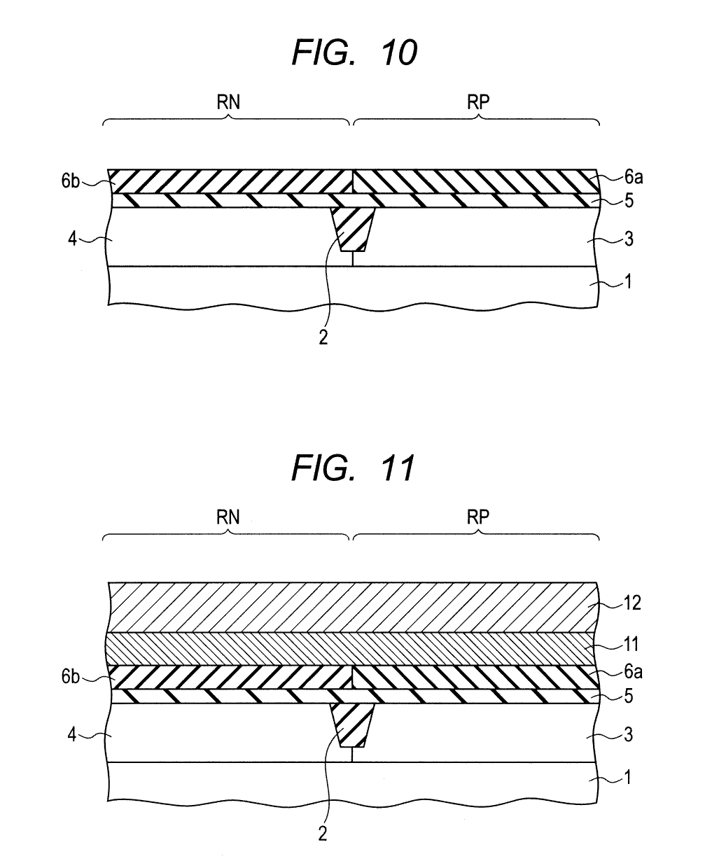

Next, by performing, e.g., a wet etching treatment or the like, a surplus of the lanthanum oxide (LaO) film 10 located in the element formation regions RP and RN is removed. By further performing a wet etching treatment or the like, the hard mask 8a located in the element formation region RP is removed. In this manner, as shown in FIG. 10, in the element formation region RN, the surface of the hafnium lanthanum oxynitride (HfLaON) film 6b is exposed. In the element formation region RP, the surface of the hafnium aluminum titanium oxynitride (HfAlTiON) film 6a is exposed.

Next, as shown in FIG. 11, a titanium nitride (TiN) film 11 is formed as a metal gate electrode material so as to come in contact with the respective surfaces of the hafnium lanthanum oxynitride (HfLaON) film 6b and the hafnium aluminum titanium oxynitride (HfAlTiON) film 6a. A polysilicon film 12 is formed so as to come in contact with the surface of the titanium nitride (TiN) film 11.

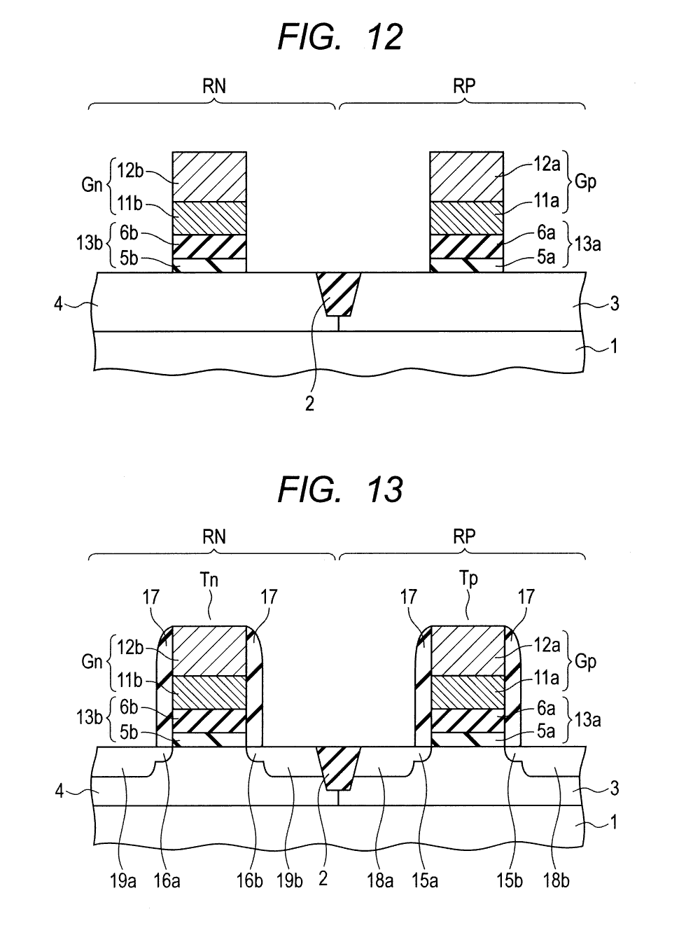

Next, by performing a predetermined photomechanical treatment and a predetermined etching treatment, as shown in FIG. 12, in the element formation region RP, a gate electrode Gp is formed over the surface of the n-type well 3 via a gate insulating film 13a. In the element formation region RN, a gate electrode Gn is formed over the surface of the p-type well 4 via a gate insulating film 13b. The gate insulating film 13a is formed of an interface layer 5a and the hafnium aluminum titanium oxynitride (HfAlTiON) film 6a, while the gate insulating film 13b is formed of an interface layer 5b and the hafnium lanthanum oxynitride (HfLaON) film 6b. The gate electrode Gp is formed of a titanium nitride (TiN) film 11a and a polysilicon film 12a, while the gate electrode Gn is formed of a titanium nitride (TiN) film 11b and a polysilicon film 12b.

Next, with the element formation region RP being covered with a resist mask (not shown), using the gate electrode Gp as a mask, p-type impurity ions are implanted into the n-type well 3 to form p-type impurity regions 15a and 15b (see FIG. 13) as LDD (Lightly Doped Drain) regions each at a predetermined depth from the surface thereof. On the other hand, with the element formation region RN being covered with a resist mask (not shown), using the gate electrode Gn as a mask, n-type impurity ions are implanted into the p-type well 4 to form n-type impurity regions 16a and 16b (see FIG. 13) as LDD regions each at a predetermined depth from the surface thereof.

Next, as shown in FIG. 13, sidewall insulating films 17 are formed over the side surfaces of the gate electrodes Gp and Gn. Then, with the element formation region RP being covered with a resist mask (not shown), using the gate electrode Gp and the sidewall insulating films 17 as a mask, p-type impurity ions are implanted into the n-type well 3 to form p-type impurity regions 18a and 18b as source/drain regions each at a predetermined depth from the surface thereof. On the other hand, with the element formation region RN being covered with a resist mask (not shown), using the gate electrode Gn and the sidewall insulating films 17 as a mask, n-type impurity ions are implanted into the p-type well 4 to form n-type impurity regions 19a and 19b as source/drain regions each at a predetermined depth from the surface thereof.

In this manner, in the element formation region RP, a p-channel field effect transistor Tp including the gate electrode Gp, and the p-type impurity regions 15a, 15b, 18a, and 18b is formed. In the element formation region RN, an n-channel field effect transistor Tn including the gate electrode Gn, and the n-type impurity regions 16a, 16b, 19a, and 19b is formed.

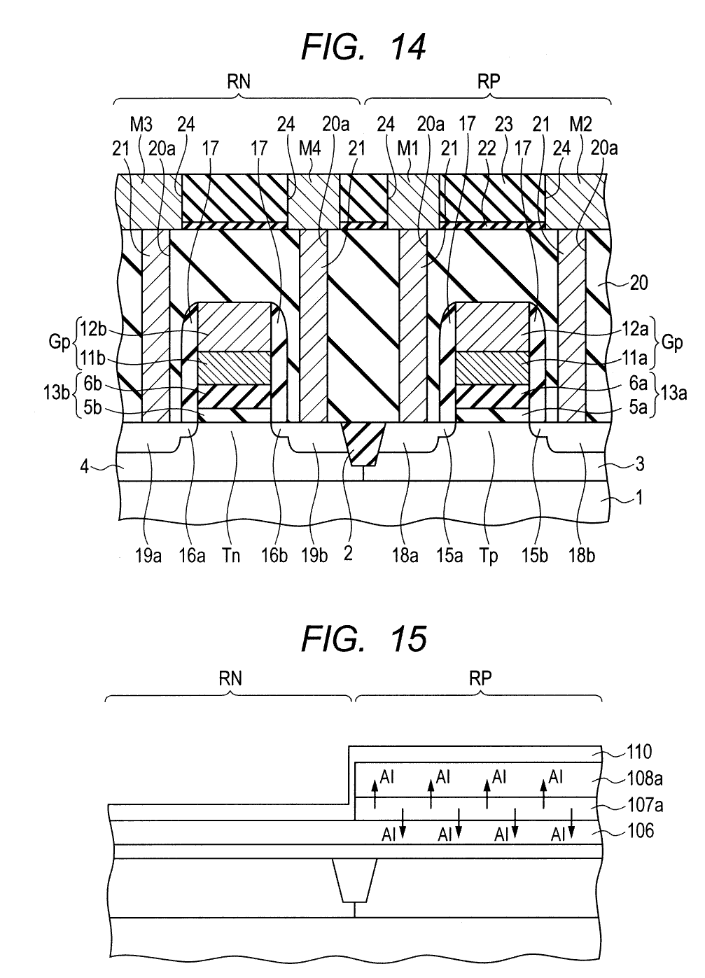

Next, as shown in FIG. 14, an interlayer insulating film is formed so as to cover the p-channel field effect transistor Tp and the n-channel field effect transistor Tn. Then, in the interlayer insulating film 20, contact holes 20a are formed to expose the surfaces of the p-type impurity regions 18a and 18b or the n-type impurity regions 19a and 19b. Then, in the contact holes 20a, plugs 21 are formed.

Next, over the interlayer insulating film 20, an etching stopper film 22 such as a silicon nitride film is formed. An interlayer insulating film 23 such as a silicon oxide film is formed so as to come in contact with the surface of the etching stopper film 22. Then, by performing a predetermined photomechanical treatment and a predetermined etching treatment, interconnect trenches 24 are formed in the interlayer insulating film 23 and the etching stopper film. A copper film (not shown) or the like is formed so as to fill the interconnect trenches 24. By performing a chemical mechanical polishing (CMP) treatment on the copper film or the like, interconnects M1, M2, M3, and M4 are formed in the interconnect trenches 24. In this manner, the main portion of the semiconductor device including the complementary field effect transistors Tp and Tn is formed.

In the semiconductor device described above, by properly using the hard mask 8a formed of the titanium aluminum nitride (TiAlN) film, it is possible to efficiently add aluminum (Al) as an element for controlling the threshold voltage of the p-channel field effect transistor to the hafnium oxynitride (HfON) film 6 located in the element formation region RP. A description will be given thereof in accordance also with a comparative example.

First, in a semiconductor device according to the comparative example, as shown in FIG. 15, a hard mask 108a covering the element formation region RP is formed of a titanium nitride (TiN) film. In this case, by a heat treatment, in the element formation region RP, aluminum (Al) in an aluminum (Al) film 107a is diffused toward a hafnium oxynitride (HfON) film 106 (see the downward arrow), while being simultaneously diffused toward the hard mask 108a (the upward arrow). Thus, aluminum (Al) is diffused toward the hard mask 108a, and accordingly the amount of aluminum (Al) eventually added to the hafnium oxynitride (HfON) film 106 is reduced undesirably. As a result, the threshold voltage of the p-channel field effect transistor may not be able to be excellently controlled. Note that, in the element formation region RN, lanthanum (La) or lanthanum oxide (LaO) in the LaO film 110 is diffused into the hafnium oxynitride (HfON) film 106, and thereby added to the hafnium oxynitride (HfON) film 106.

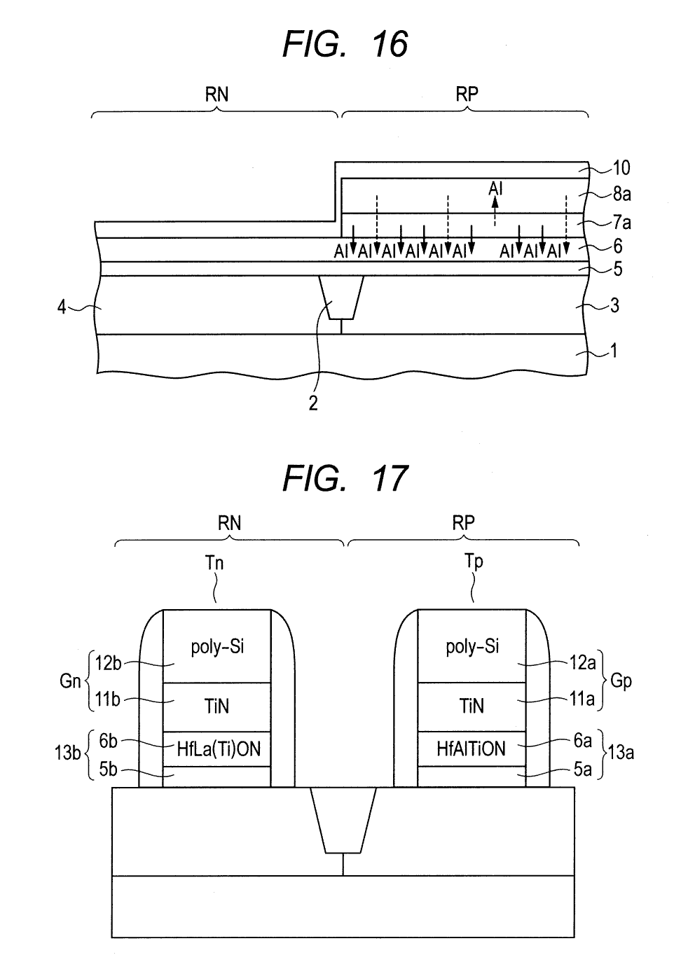

In contrast to the semiconductor device according to the comparative example, in the semiconductor device described above, as shown in FIG. 16, the hard mask 8a covering the element formation region RP is formed of the titanium aluminum nitride (TiAlN) film containing aluminum (Al) as an element. Accordingly, compared with the case with the hard mask 108a not containing aluminum (Al), the diffusion of aluminum (Al) from the aluminum (Al) film 7a into the hard mask 8a is suppressed. Thus, the diffusion of aluminum (Al) into the hard mask 8a is suppressed, and accordingly aluminum (Al) in the aluminum (Al) film 7a is sufficiently diffused (see the downward arrow) toward the hafnium oxynitride (HfON) film 6. In addition, aluminum (Al) in the hard mask 8a is also diffused into the hafnium oxynitride (HfON) film 6 through the aluminum (Al) film 7a. As a result, it is possible to reliably control the threshold voltage of the p-channel field effect transistor.

On the other hand, in the element formation region RN, lanthanum (La) or lanthanum oxide (LaO) in the LaO film 10 is diffused into the hafnium oxynitride (HfON) film 6, and thereby added to the hafnium oxynitride (HfON) film 6. Note that, in the element formation region RP, the hard mask 8a is formed, and therefore lanthanum (La) or lanthanum oxide (LaO) in the LaO film 10 is prevented from being diffused into the hafnium oxynitride (HfON) film 6.

Note that, in the element formation region RP, when the heat treatment is performed, titanium (Ti) in the hard mask 8a is also diffused into the hafnium oxynitride (HfON) film 6 through the aluminum (Al) film 7a. As a result, to the hafnium oxynitride (HfON) film 6, titanium (Ti) is also added as an element besides aluminum (Al) to form the hafnium aluminum titanium oxynitride (HfAlTiON) film 6a. Here, an advantage achieved by the addition of titanium (Ti) will be described.

First, parameters which determine a characteristic of a field effect transistor to which a High-k film such as a hafnium oxynitride (HfON) film and a metal gate electrode are applied include an effective work function (EWF) and an equivalent oxide thickness (EOT) of a gate insulating film. Here, the equivalent oxide thickness is a thickness of a gate insulating film converted to that of a silicon dioxide (SiO₂) film. As the effective work function, a high value (e.g., 5.1 eV) is required for the p-channel field effect transistor, while a low value (e.g., 4.1 eV) is required for the n-channel field effect transistor. The equivalent oxide thickness is required to be reduced in each of the p-channel field effect transistor and the n-channel field effect transistor.

In particular, in the p-channel field effect transistor, by adding aluminum (Al) to the hafnium oxynitride (HfON) film as the gate insulating film, the effective work function can be set at a high value. In addition, by increasing the dielectric constant of the gate insulating film, the equivalent oxide thickness of the gate insulating film can be reduced. However, the dielectric constant of the hafnium aluminum oxynitride (HfAlON) film obtained by adding aluminum (Al) to the hafnium oxynitride (HfON) film is lower than the dielectric constant of the hafnium oxynitride (HfON) film. As a result, the equivalent oxide thickness of the hafnium aluminum oxynitride (HfAlON) film is undesirably larger than the equivalent oxide thickness of the hafnium oxynitride (HfON) film.

By contrast, titanium (Ti) has the property of increasing the dielectric constant of the hafnium oxynitride (HfON) film when added thereto. Accordingly, by further diffusing titanium (Ti) from the hard mask 8a into the hafnium aluminum oxynitride (HfAlON) film to which aluminum (Al) has been added, the dielectric constant of the hafnium aluminum titanium oxynitride (HfAlTiON) film 6a is increased to be higher than the dielectric constant of the hafnium aluminum oxynitride (HfAlON) film. Accordingly, the equivalent oxide thickness of the hafnium aluminum titanium oxynitride (HfAlTiON) film 6a is smaller than the equivalent oxide thickness of the hafnium aluminum oxynitride (HfAlON) film that has been increased by the addition of aluminum (Al). That is, the equivalent oxide thickness of the gate insulating film (High-k film) that has been increased by the addition of aluminum (Al) can be reduced by adding titanium (Ti) thereto. Therefore a desired characteristic can be obtained from the p-channel field effect transistor.

In the semiconductor device thus formed, as shown in FIG. 17, the gate electrode of the p-channel field effect transistor Tp has a structure such that, over the hafnium aluminum titanium oxynitride (HfAlTiON) film 6a as a High-k film (gate insulating film), the gate electrode including the titanium nitride (TiN) film 11a and the polysilicon film 12a is stacked. On the other hand, the gate electrode of the n-channel field effect transistor Tn has a structure such that, over the hafnium lanthanum oxynitride (HfLaON) film 6b as a High-k film, the gate electrode including the titanium nitride (TiN) film 11b and the polysilicon film 12b is stacked.

Note that, by the heat treatment after the titanium nitride (TiN) film serving as each of the gate electrodes is formed, titanium (Ti) in the titanium nitride film is considered to be diffused into the hafnium lanthanum oxynitride (HfLaON) film 6b. In the hafnium lanthanum oxynitride (HfLaON) film 6b of the n-channel field effect transistor shown in FIG. 17, “Ti” is shown by assuming the case where Ti is added through such diffusion. By evaluation performed by the present inventors, it has been verified that the amount of titanium (Ti) in the hafnium aluminum titanium oxynitride (HfAlTiON) film 6a is sufficiently large.

### Second Embodiment

Here, a semiconductor device will be described in which an aluminum oxide (AlO) film is used properly as a film for controlling the threshold voltage of the p-channel field effect transistor.

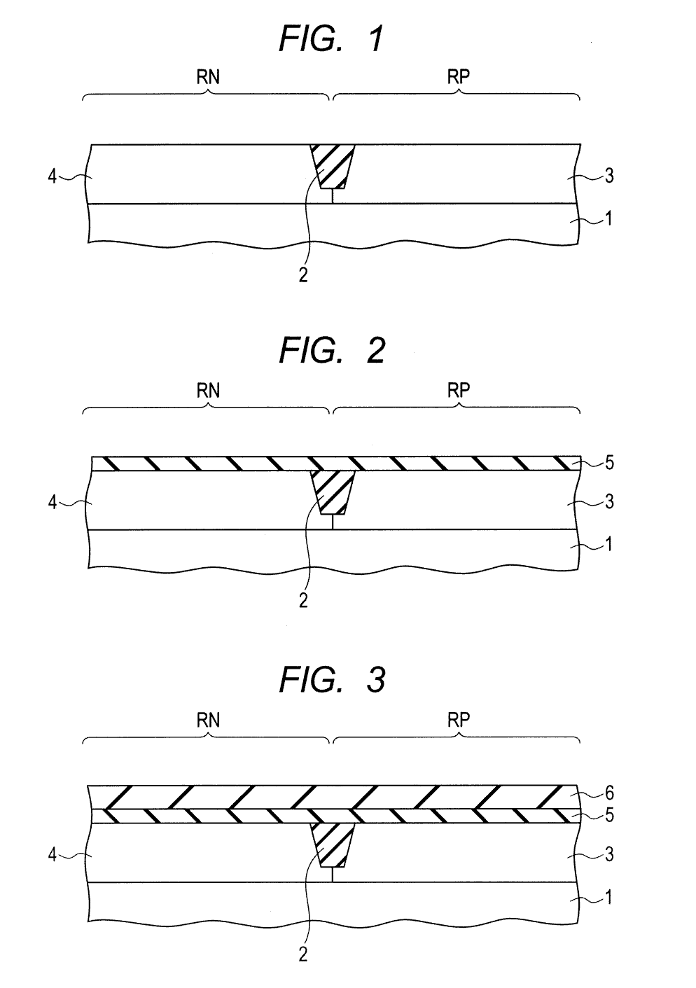

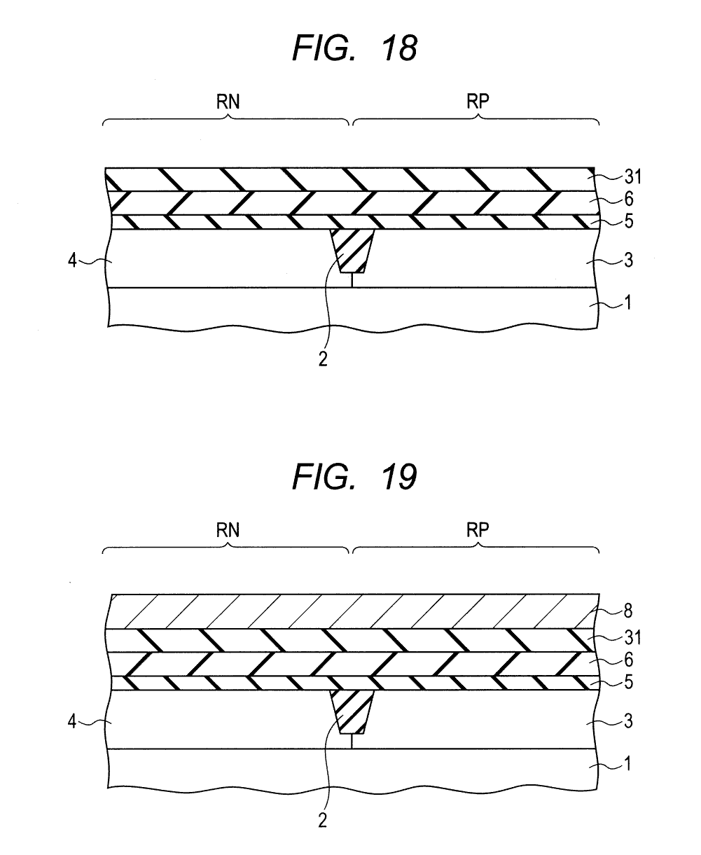

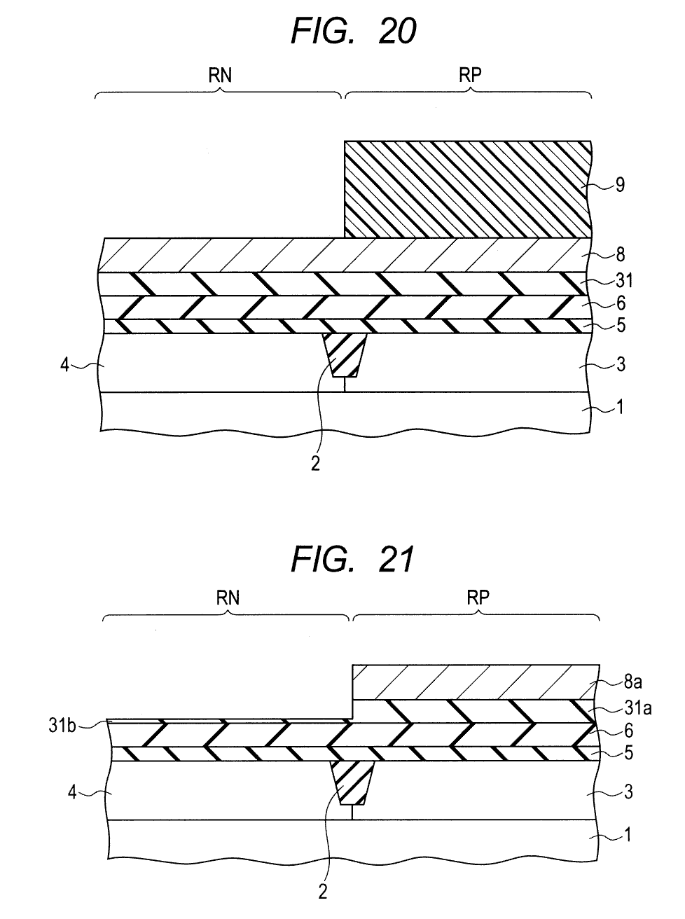

After the steps shown in FIGS. 1 to 3, as shown in FIG. 18, an aluminum oxide (AlO) film 31 is formed so as to come in contact with the surface of the hafnium oxynitride (HfON) film 6. Then, as shown in FIG. 19, the titanium aluminum nitride (TiAlN) film 8 having a thickness of about 10 nm is formed so as to come in contact with the surface of the aluminum oxide (AlO) film 31. Then, as shown in FIG. 20, the resist mask 9 covering the element formation region RP and exposing the element formation region RN is formed.

Next, using the resist mask 9 as an etching mask, a wet etching treatment is performed to remove the respective portions of the titanium aluminum nitride (TiAlN) film 8 and the aluminum oxide (AlO) film 31 exposed in the element formation region RP. At this time, if it is attempted to completely remove the aluminum oxide (AlO) film 31, the surface of the hafnium oxynitride (HfON) film 6 may be damaged. To avoid the damage, the removal is performed so as to leave an aluminum oxide (AlO) film 31b. Thereafter, by removing the resist mask 9, as shown in FIG. 21, the hard mask 8a covering the element formation region RP is formed. Then, as shown in FIG. 22, the lanthanum oxide (LaO) film 10 having a thickness of about 0.5 nm is formed so as to cover the aluminum oxide (AlO) film 31b located in the element formation region RN and the hard mask 8a located in the element formation region RP.

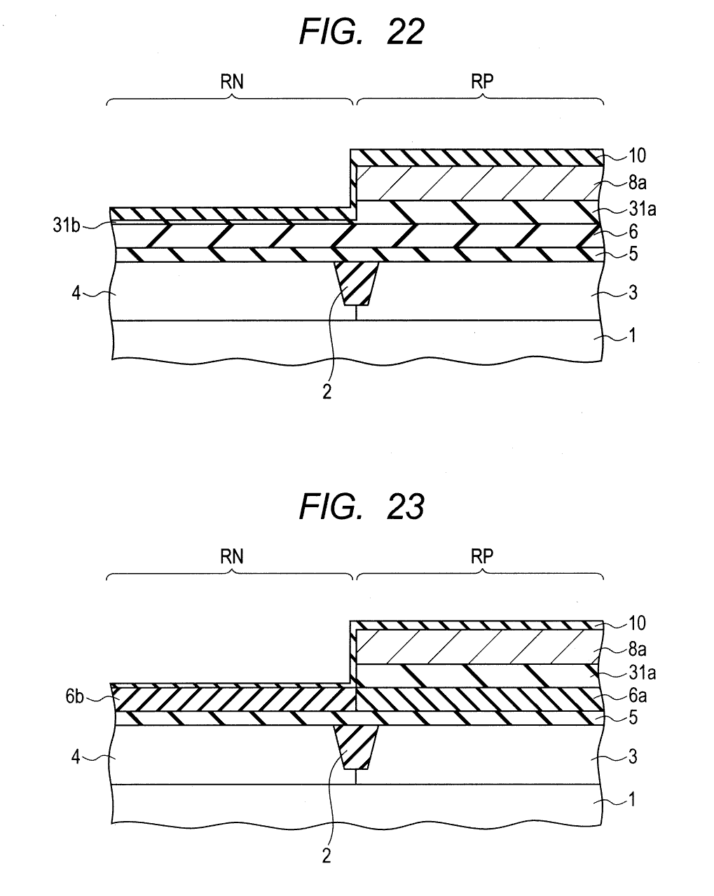

Next, as shown in FIG. 23, a heat treatment is performed at a temperature of about 700 to 900° C. As the heat treatment proceeds, in the element formation region RN, lanthanum (La) or lanthanum oxide (LaO) in the lanthanum oxide (LaO) film 10 and aluminum (Al) or aluminum oxide (AlO) in the aluminum oxide (AlO) film 31b are diffused together into the hafnium oxynitride (HfON) film 6, and thereby added as elements to the hafnium oxynitride (HfON) film 6 to form a hafnium aluminum lanthanum oxynitride (HfAlLaON) film 6b. Thus, in the element formation region RN, as a High-k film, a film formed of the hafnium aluminum lanthanum oxynitride (HfAlLaON) film 6b is formed.

On the other hand, in the element formation region RP, aluminum (Al) (element) or aluminum oxide (AlO) in the aluminum oxide (AlO) film 31a is diffused into the hafnium oxynitride (HfON) film 6, and thereby added as an element to the hafnium oxynitride (HfON) film 6. In addition, aluminum (Al) and titanium (Ti) in the hard mask 8a formed of the titanium aluminum nitride (TiAlN) film are diffused into the hafnium oxynitride (HfON) film 6, and thereby added as elements to the hafnium oxynitride (HfON) film 6. Thus, in the element formation region RP, aluminum (Al) and titanium (Ti) are added as elements to the hafnium oxynitride (HfON) film 6 to form the hafnium aluminum titanium oxynitride (HfAlTiON) film 6a.

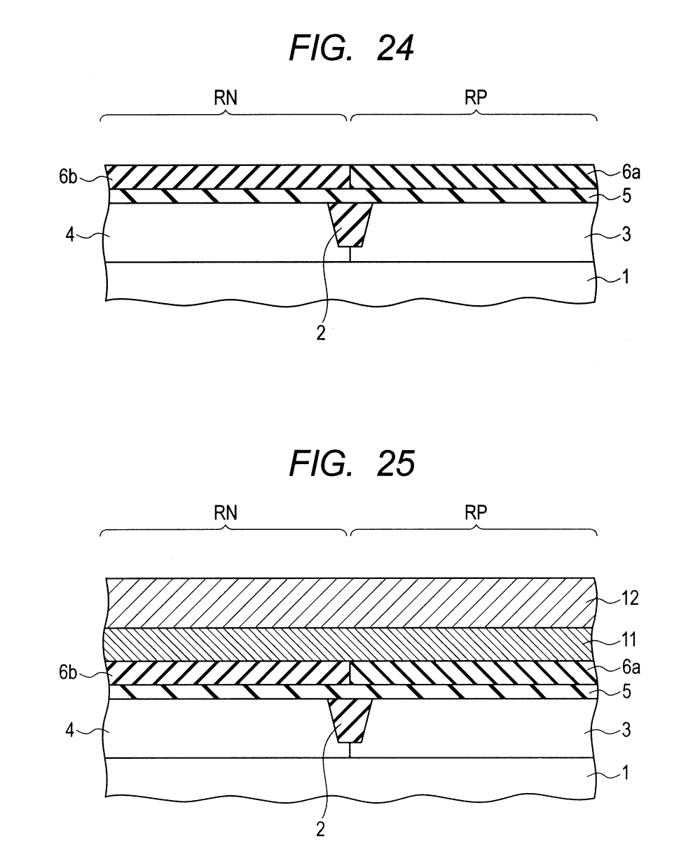

Next, by performing, e.g., a wet etching treatment or the like, a surplus of the lanthanum oxide (LaO) film 10 located in the element formation regions RP and RN is removed. By further performing a wet etching treatment or the like, the hard mask 8a located in the element formation region RP is removed. In this manner, as shown in FIG. 24, in the element formation region RN, the surface of the hafnium aluminum lanthanum oxynitride (HfAlLaON) film 6b is exposed. In the element formation region RP, the surface of the hafnium aluminum titanium oxynitride (HfAlTiON) film 6a is exposed.

Next, as shown in FIG. 25, the titanium nitride (TiN) film 11 is formed as the metal gate electrode material so as to come in contact with the respective surfaces of the hafnium aluminum lanthanum oxynitride (HfAlLaON) film 6b and the hafnium aluminum titanium oxynitride (HfAlTiON) film 6a. The polysilicon film 12 is formed so as to come in contact with the surface of the titanium nitride (TiN) film 11.

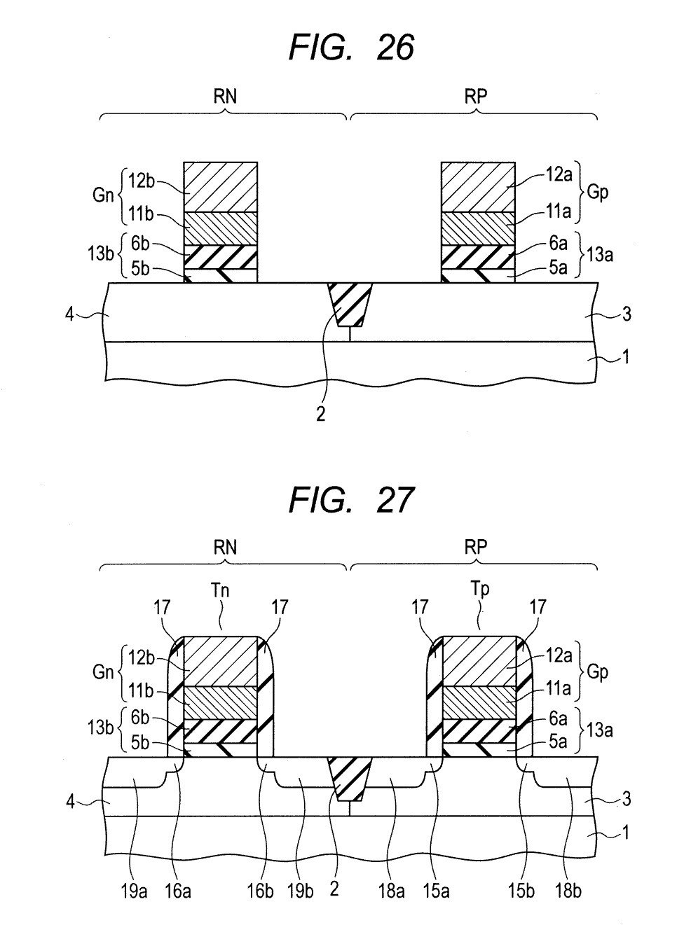

Next, through the same step as the step shown in FIG. 12, as shown in FIG. 26, in the element formation region RP, the gate electrode Gp is formed over the surface of the n-type well 3 via the gate insulating film 13a. In the element formation region RN, the gate electrode Gn is formed over the surface of the p-type well 4 via the gate insulating film 13b. The gate insulating film 13a is formed of the interface layer 5a and the hafnium aluminum titanium oxynitride (HfAlTiON) film 6a, while the gate insulating film 13b is formed of the interface layer 5b and the hafnium aluminum lanthanum oxynitride (HfAlLaON) film 6b. The gate electrode Gp is formed of the titanium nitride (TiN) film 11a and the polysilicon film 12a, while the gate electrode Gn is formed of the titanium nitride (TiN) film 11b and the polysilicon film 12b.

Next, through the same step as the step shown in FIG. 13, as shown in FIG. 27, in the n-type well 3, the p-type impurity regions 15a and 15b are formed as the LDD regions each at a predetermined depth from the surface thereof, and the p-type impurity regions 18a and 18b are formed as the source/drain regions each at a predetermined depth from the surface thereof. In the p-type well 4, the n-type impurity regions 16a and 16b are formed as the LDD regions each at a predetermined depth from the surface thereof, and the n-type impurity regions 19a and 19b are formed as the source/drain regions each at a predetermined depth from the surface thereof.

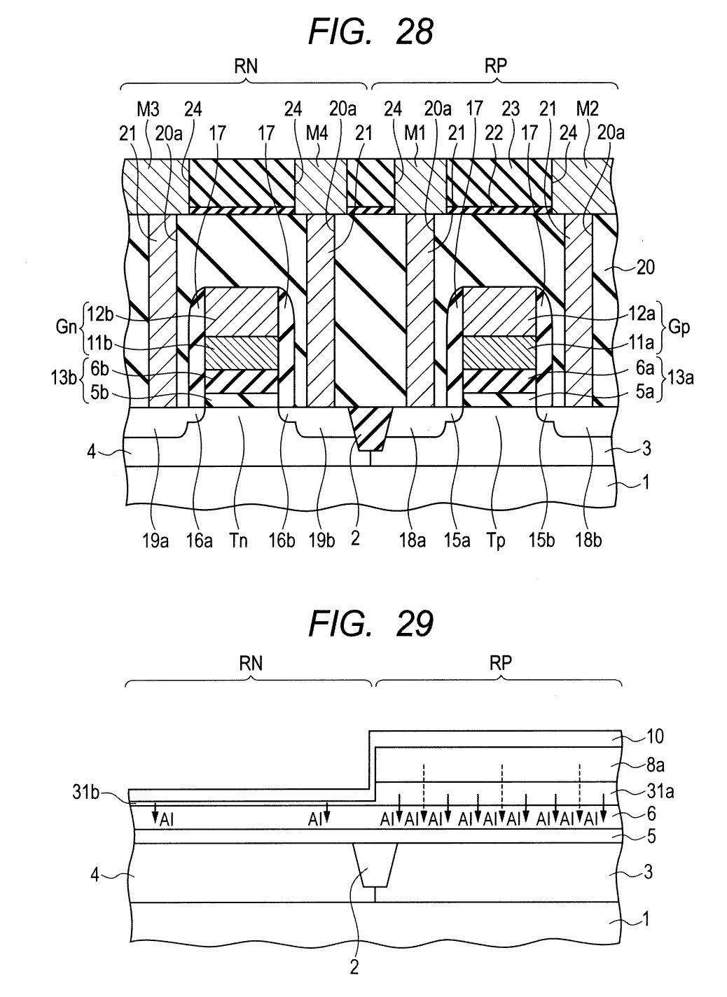

Next, through the same step as the step shown in FIG. 14, as shown in FIG. 28, the interconnects M1 and M2 electrically coupled to the p-type impurity regions 18a and 18b of the p-channel field effect transistor Tp via the plugs 21 and the like are formed. Also, the interconnects M3 and M4 electrically coupled to the n-type impurity regions 19a and 19b of the n-channel field effect transistor Tn via the plugs 21 and the like are formed. In this manner, the main portion of the semiconductor device is formed.

In the semiconductor device described above, as shown in FIG. 29, the hard mask 8a covering the element formation region RP is formed of the titanium aluminum nitride (TiAlN) film containing aluminum (Al) as an element. Therefore, compared with the case with the hard mask 108a not containing aluminum (Al), the diffusion of aluminum (Al) as an element from the aluminum oxide (AlO) film 31a into the hard mask 8a can be suppressed. Thus, the diffusion of aluminum (Al) into the hard mask 8a is suppressed, and accordingly aluminum (Al) (element) in the aluminum oxide (AlO) film 31a is sufficiently diffused toward the hafnium oxynitride (HfON) film 6 (see the downward arrow). In addition, aluminum (Al) in the hard mask 8a is also diffused into the hafnium oxynitride (HfON) film 6 through the aluminum oxide (AlO) film 31a. As a result, it is possible to reliably control the threshold voltage of the p-channel field effect transistor.

When the heat treatment is performed, titanium (Ti) in the hard mask 8a is also diffused into the hafnium oxynitride (HfON) film 6 through the aluminum (Al) film 7a. As a result, to the hafnium oxynitride (HfON) film 6, titanium (Ti) is also added as an element besides aluminum (Al) to form the hafnium aluminum titanium oxynitride (HfAlTiON) film 6a. As a result, as already described, the equivalent oxide thickness of the gate insulating film (High-k film) that has been increased by the addition of aluminum (Al) can be reduced by adding titanium (Ti) thereto. Therefore, a desired characteristic can be obtained from the p-channel field effect transistor.

On the other hand, in the element formation region RN, lanthanum (La) or lanthanum oxide (LaO) in the LaO film 10 is diffused into the hafnium oxynitride (HfON) film 6, and thereby added to the hafnium oxynitride (HfON) film 6.

In the semiconductor device thus formed, as shown in FIG. 30, the gate electrode of the p-channel field effect transistor Tp has a structure such that, over the hafnium aluminum titanium oxynitride (HfAlTiON) film 6a as a High-k film, the gate electrode Gp including the titanium nitride (TiN) film 11a and the polysilicon film 12a is stacked. On the other hand, the gate electrode of the n-channel field effect transistor Tn has a structure such that, over the hafnium aluminum lanthanum oxynitride (HfAlLaON) film 6b as a High-k film, the gate electrode Gn including the titanium nitride (TiN) film 11b and the polysilicon film 12b is stacked.

Note that, as described above, the case may also be assumed where, by the heat treatment after the titanium nitride (TiN) film serving as each of the gate electrodes is formed, titanium (Ti) in the titanium nitride film is diffused into the hafnium aluminum lanthanum oxynitride (HfAlLaON) film 6b. In the hafnium lanthanum aluminum oxynitride (HfLaAlON) film 6b of the n-channel field effect transistor shown in FIG. 30, “Ti” is shown by assuming the case where Ti is added through such diffusion.

### Third Embodiment

Here, a semiconductor device will be described in which a hard mask is used properly as a film containing elements for controlling the threshold voltage of the p-channel field effect transistor.

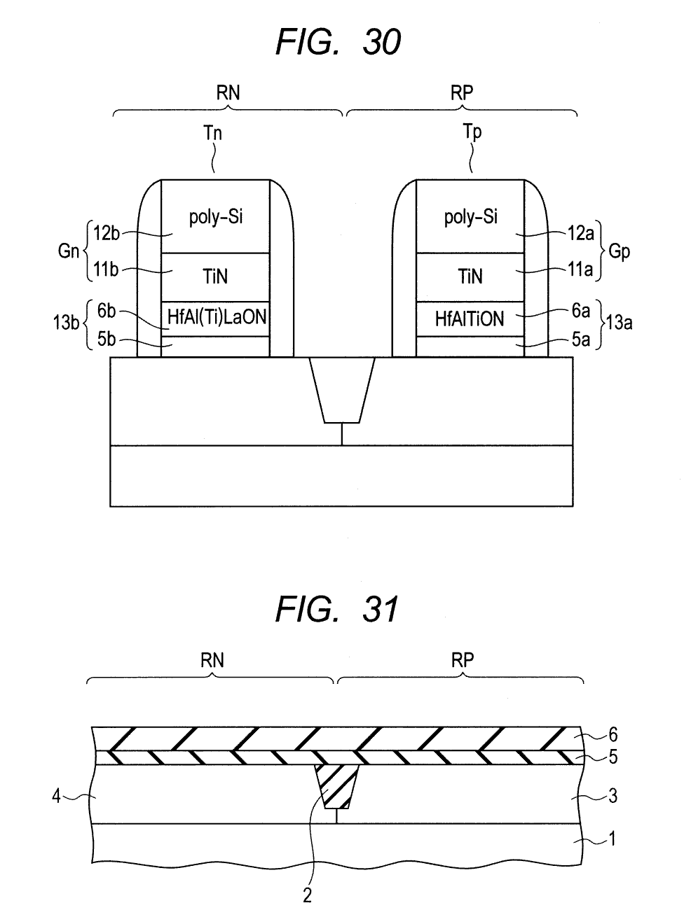

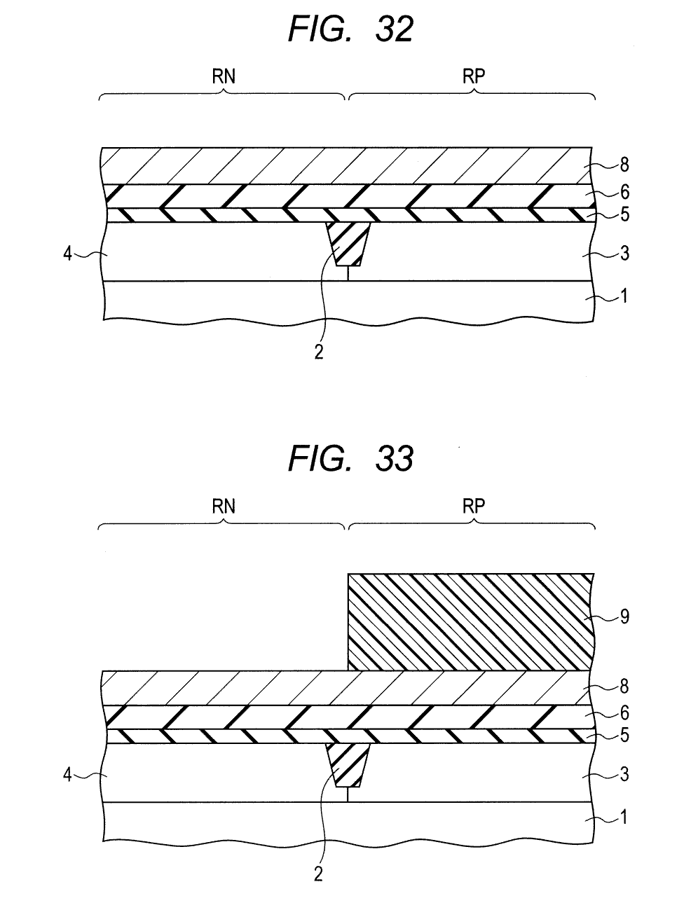

Through the same steps as the steps shown in FIGS. 1 to 3, as shown in FIG. 31, the hafnium oxynitride (HfON) film 6 is formed so as to come in contact with the surface of the interface layer 5. Then, as shown in FIG. 32, the titanium aluminum nitride (TiAlN) film 8 having a thickness of about 10 nm is formed so as to come in contact with the surface of the hafnium oxynitride (HfON) film 6. Then, as shown in FIG. 33, the resist mask 9 covering the element formation region RP and exposing the element formation region RN is formed.

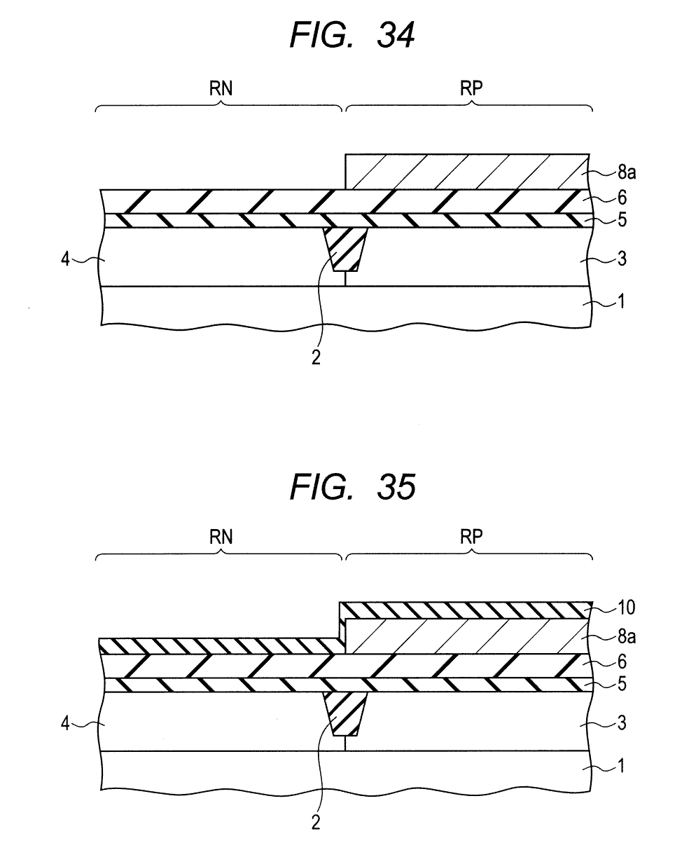

Next, using the resist mask 9 as an etching mask, a wet etching treatment is performed to remove the portion of the titanium aluminum nitride (TiAlN) film 8 exposed in the element formation region RN to expose the surface of the hafnium oxynitride (HfON) film 6. Thereafter, by removing the resist mask 9, as shown in FIG. 34, the hard mask 8a covering the element formation region RP is formed. On the other hand, in the element formation region RN, the surface of the hafnium oxynitride (HfON) film 6 is exposed. Then, as shown in FIG. 35, the lanthanum oxide (LaO) film 10 having a thickness of about 0.5 nm is formed so as to cover the hafnium oxynitride (HfON) film 6 exposed in the element formation region RN and the hard mask 8a located in the element formation region RP.

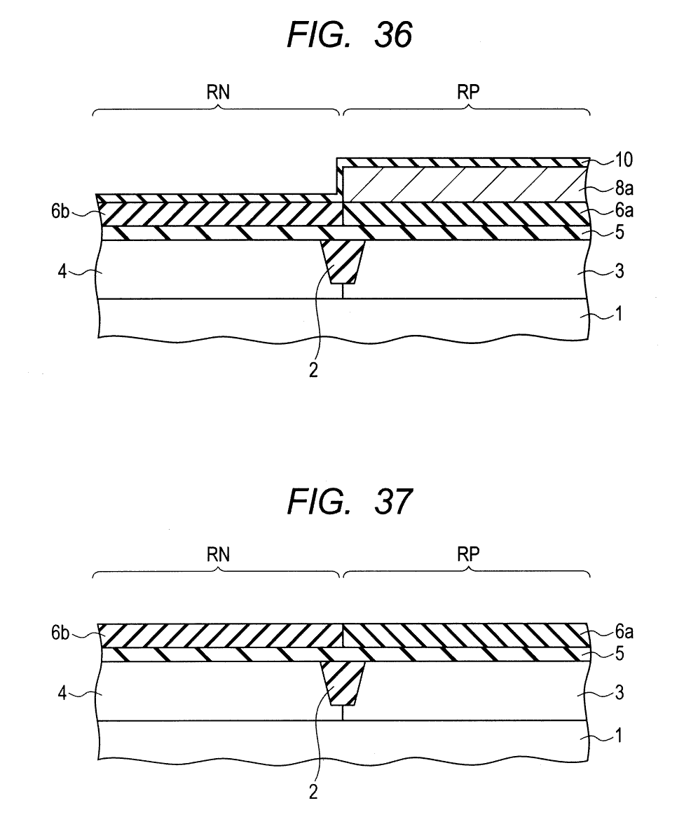

Next, as shown in FIG. 36, a heat treatment is performed at a temperature of about 700 to 900° C. As the heat treatment proceeds, in the element formation region RN, lanthanum (La) or lanthanum oxide (LaO) in the lanthanum oxide (LaO) film 10 is diffused into the hafnium oxynitride (HfON) film 6, and thereby added as an element to the hafnium oxynitride (HfON) film 6 to form the hafnium lanthanum oxynitride (HfLaON) film 6b.

On the other hand, in the element formation region RP, aluminum (Al) and titanium (Ti) in the hard mask 8a formed of the titanium aluminum nitride (TiAlN) film are diffused into the hafnium oxynitride (HfON) film 6, and thereby added as elements to the hafnium oxynitride (HfON) film 6 to form the hafnium aluminum titanium oxynitride (HfAlTiON) film 6a.

Next, by performing, e.g., a wet etching treatment or the like, a surplus of the lanthanum oxide (LaO) film 10 located in the element formation regions RP and RN is removed. By further performing a wet etching treatment or the like, the hard mask 8a located in the element formation region RP is removed. In this manner, as shown in FIG. 37, in the element formation region RN, the surface of the hafnium lanthanum oxynitride (HfLaON) film 6b is exposed. In the element formation region RP, the surface of the hafnium aluminum titanium oxynitride (HfAlTiON) film 6a is exposed.

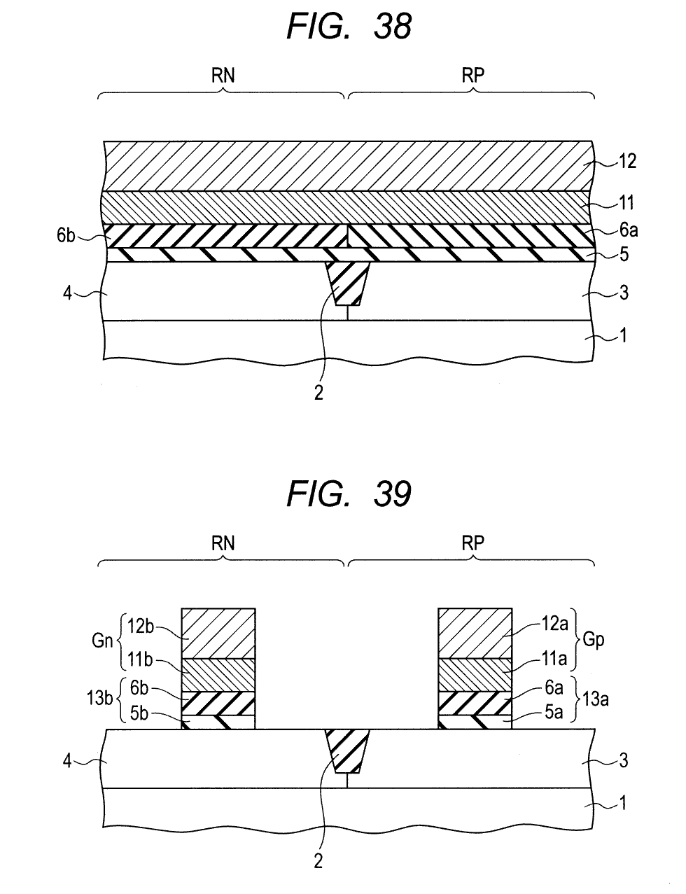

Next, as shown in FIG. 38, the titanium nitride (TiN) film 11 is formed as the metal gate electrode material so as to come in contact with the respective surfaces of the hafnium lanthanum oxynitride (HfLaON) film 6b and the hafnium aluminum titanium oxynitride (HfAlTiON) film 6a. The polysilicon film 12 is formed so as to come in contact with the surface of the titanium nitride (TiN) film 11.

Next, through the same step as the step shown in FIG. 12, as shown in FIG. 39, in the element formation region RP, the gate electrode Gp is formed over the surface of the n-type well 3 via the gate insulating film 13a. In the element formation region RN, the gate electrode Gn is formed over the surface of the p-type well 4 via the gate insulating film 13b. The gate insulating film 13a is formed of the interface layer 5a and the hafnium aluminum titanium oxynitride (HfAlTiON) film 6a, while the gate insulating film 13b is formed of the interface layer 5b and the hafnium lanthanum oxynitride (HfLaON) film 6b. The gate electrode Gp is formed of the titanium nitride (TiN) film 11a and the polysilicon film 12a, while the gate electrode Gn is formed of the titanium nitride (TiN) film 11b and the polysilicon film 12b.

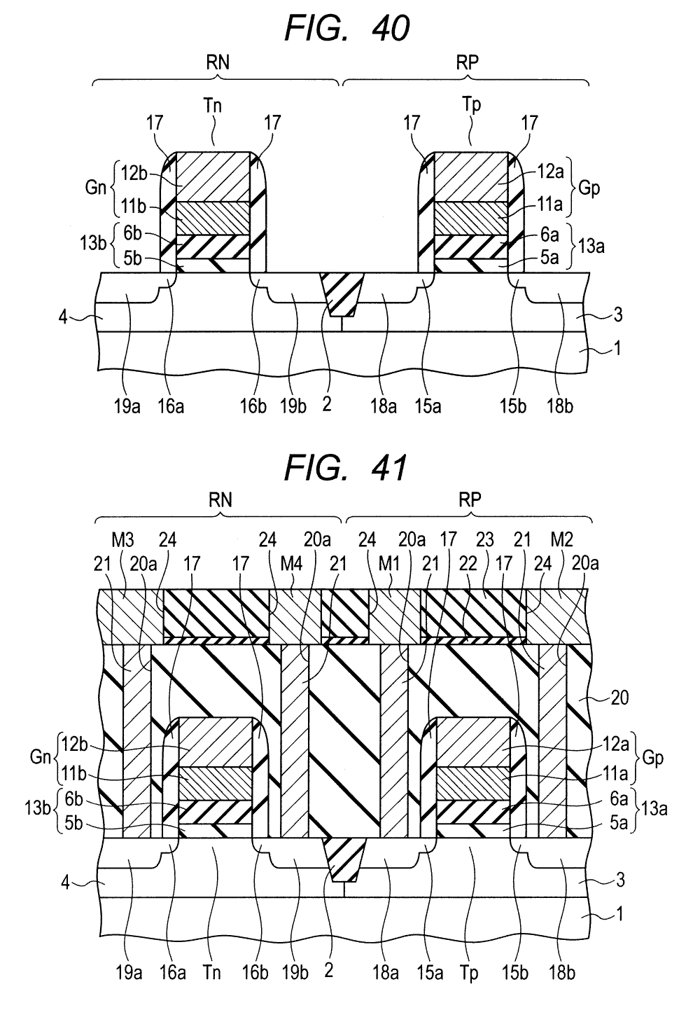

Next, through the same step as the step shown in FIG. 13, as shown in FIG. 40, in the n-type well 3, the p-type impurity regions 15a and 15b are formed as the LDD regions each at a predetermined depth from the surface thereof, and the p-type impurity regions 18a and 18b are formed as the source/drain regions each at a predetermined depth from the surface thereof. In the p-type well 4, the n-type impurity regions 16a and 16b are formed as the LDD regions each at a predetermined depth from the surface thereof, and the n-type impurity regions 19a and 19b are formed as the source/drain regions each at a predetermined depth from the surface thereof.

Next, through the same step as the step shown in FIG. 14, as shown in FIG. 41, the interconnects M1 and M2 electrically coupled to the p-type impurity regions 18a and 18b of the p-channel field effect transistor Tp via the plugs 21 and the like are formed. Also, the interconnects M3 and M4 electrically coupled to the n-type impurity regions 19a and 19b of the n-channel field effect transistor Tn via the plugs 21 and the like are formed. In this manner, the main portion of the semiconductor device is formed.

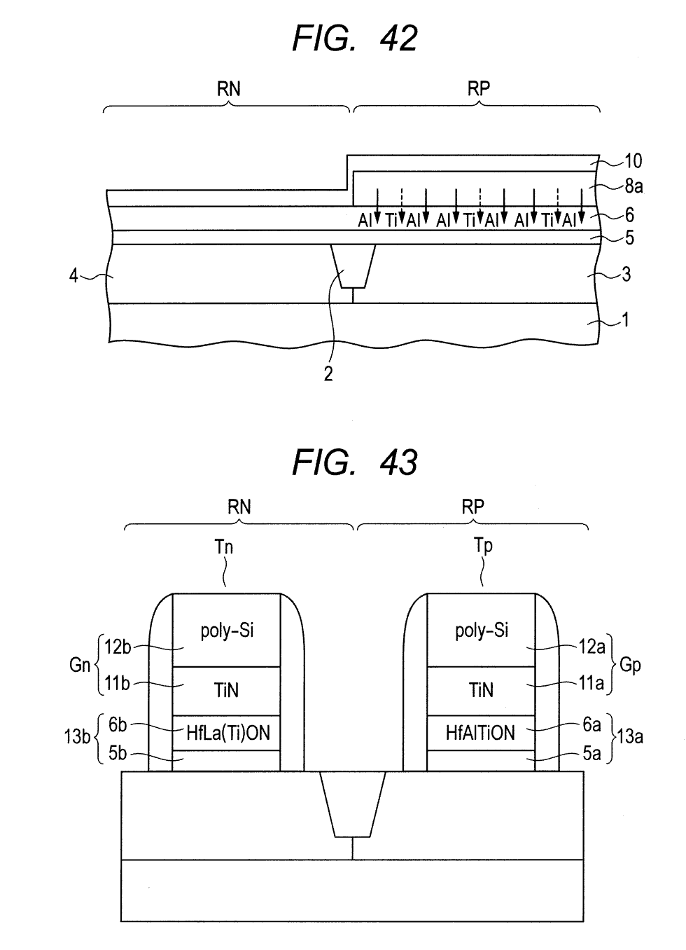

In the semiconductor device described above, as shown in FIG. 42, the hard mask 8a covering the element formation region RP is formed of a titanium aluminum nitride (TiAlN) film containing aluminum (Al) as an element. Accordingly, when the heat treatment is performed, aluminum (Al) (element) in the hard mask 8a is diffused into the hafnium oxynitride (HfON) film 6, and thereby added to the hafnium oxynitride (HfON) film 6. That is, by causing aluminum (Al) in the titanium aluminum nitride (TiAlN) film to be added to the hafnium oxynitride (HfON) film 6, it is possible to omit the step of forming the aluminum (Al) film 7 described in the first embodiment, and achieve a reduction in steps.

In addition, titanium (Ti) in the hard mask 8a is also diffused into the hafnium oxynitride (HfON) film 6 so that, to the hafnium oxynitride (HfON) film 6, aluminum (Al) and titanium (Ti) are added as elements to form the hafnium aluminum titanium oxynitride (HfAlTiON) film 6a. As a result, as already described, the equivalent oxide thickness of the gate insulating film (High-k film) that has been increased by the addition of aluminum (Al) can be reduced by adding titanium (Ti) thereto. Therefore, a desired characteristic can be obtained from the p-channel field effect transistor.

On the other hand, in the element formation region RN, lanthanum (La) or lanthanum oxide (LaO) in the LaO film 10 is diffused into the hafnium oxynitride (HfON) film 6, and thereby added to the hafnium oxynitride (HfON) film 6.

In the semiconductor device thus formed, as shown in FIG. 43, the gate electrode of the p-channel field effect transistor Tp has a structure such that, over the hafnium aluminum titanium oxynitride (HfAlTiON) film 6a as a High-k film, the gate electrode Gp including the titanium nitride (TiN) film 11a and the polysilicon film 12a is stacked. On the other hand, the gate electrode of the n-channel field effect transistor Tn has a structure such that, over the hafnium lanthanum oxynitride (HfLaON) film 6b as a High-k film, the gate electrode Gn including the titanium nitride (TiN) film 11b and the polysilicon film 12b is stacked.

Note that, as described above, the case may also be assumed where, by the heat treatment after the titanium nitride (TiN) film serving as each of the gate electrodes is formed, titanium (Ti) in the titanium nitride film is diffused into the hafnium lanthanum oxynitride (HfLaON) film 6b. In the hafnium lanthanum oxynitride (HfLaON) film 6b of the n-channel field effect transistor shown in FIG. 43, “Ti” is shown by assuming the case where Ti is added through such diffusion.

### Fourth Embodiment

Here, a semiconductor device will be described in which a titanium nitride (TiN) film is used properly as a hard mask. The titanium nitride (TiN) film in the present embodiment is different from the titanium nitride film in the semiconductor device according to the comparative example described in the first embodiment in that the composition ratio (element ratio) of nitrogen to titanium is within a predetermined range.

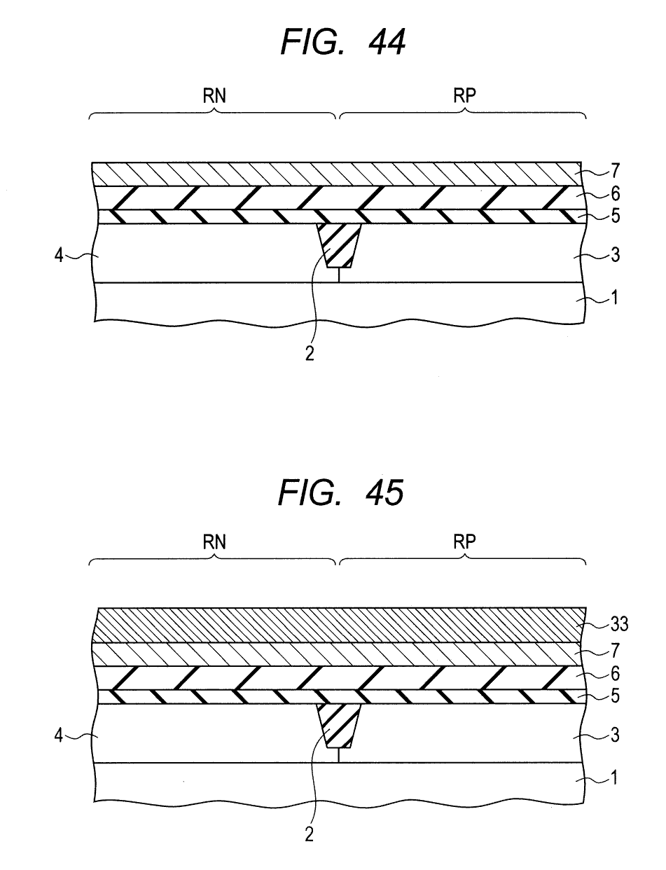

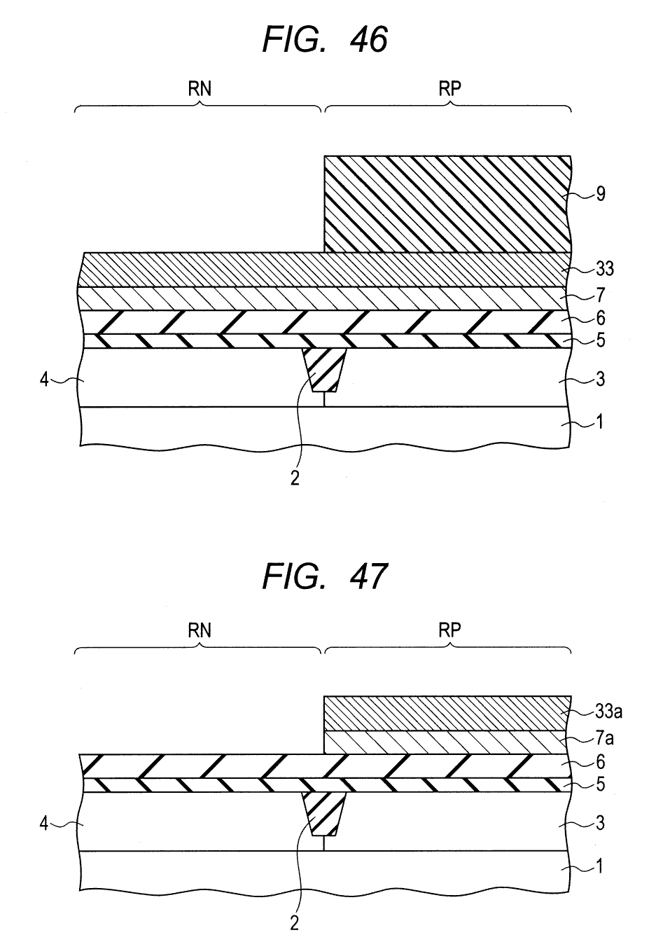

Through the same steps as the steps shown in FIGS. 1 to 4, as shown in FIG. 44, the aluminum (Al) film 7 is formed so as to come in contact with the surface of the hafnium oxynitride (HfON) film 6. Then, as shown in FIG. 45, a titanium nitride (TiN) film 33 having a predetermined composition ratio between titanium (Ti) and nitrogen (N) is formed so as to come in contact with the surface of the aluminum (Al) film 7. The composition ratio will be described later. Then, as shown in FIG. 46, the resist mask 9 covering the element formation region RP and exposing the element formation region RN is formed.

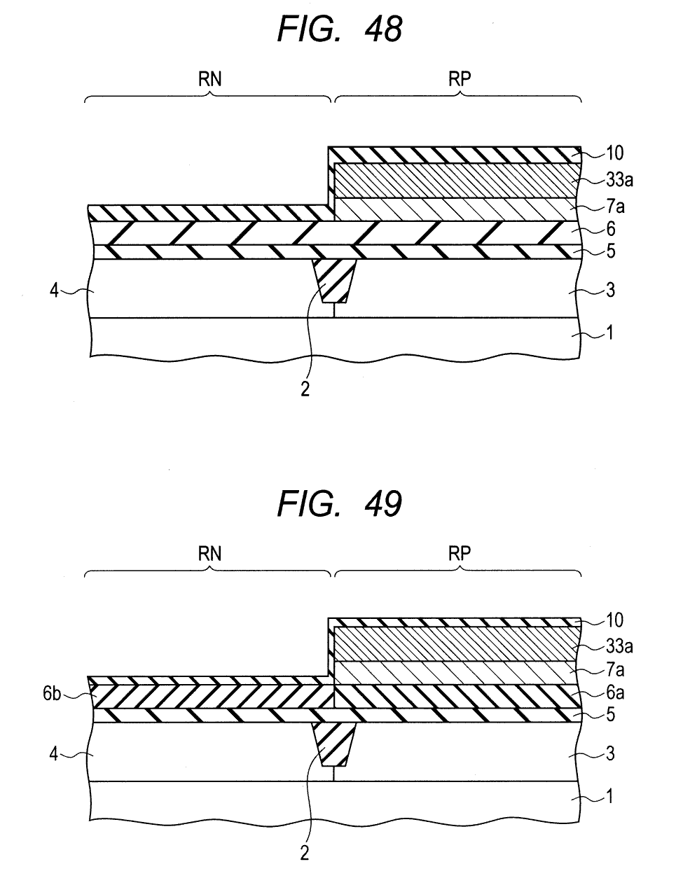

Next, using the resist mask 9 as an etching mask, a wet etching treatment is performed to remove the portion of the aluminum (Al) film 7 exposed in the element formation region RN to expose the surface of the hafnium oxynitride (HfON) film 6. Thereafter, by removing the resist mask 9, as shown in FIG. 47, a hard mask 33a covering the element formation region RP is formed. On the other hand, in the element formation region RN, the surface of the hafnium oxynitride (HfON) film 6 is exposed. Then, as shown in FIG. 48, the lanthanum oxide (LaO) film 10 having a thickness of about 0.5 nm is formed so as to cover the hafnium oxynitride (HfON) film 6 exposed in the element formation region RN and the hard mask 33a located in the element formation region RP.

Next, as shown in FIG. 49, a heat treatment is performed at a temperature of about 700 to 900° C. As the heat treatment proceeds, in the element formation region RN, lanthanum (La) or lanthanum oxide (LaO) in the lanthanum oxide (LaO) film 10 is diffused into the hafnium oxynitride (HfON) film 6, and thereby added as an element to the hafnium oxynitride (HfON) film 6 to form the hafnium lanthanum oxynitride (HfLaON) film 6b.

On the other hand, in the element formation region RP, aluminum (Al) in the aluminum (Al) film 7a is diffused into the hafnium oxynitride (HfON) film 6, and thereby added as an element to the hafnium oxynitride (HfON) film 6. In addition, titanium (Ti) in the hard mask 33a formed of the titanium nitride (TiN) film is diffused into the hafnium oxynitride (HfON) film 6, and thereby added as an element to the hafnium oxynitride (HfON) film 6. Moreover, by the setting of the composition ratio R between titanium (Ti) and nitrogen (N) in the titanium nitride (TiN) film within a predetermined range (1≦R≦1.1), the diffusion of nitrogen (N) from the hard mask 33a into the hafnium oxynitride (HfON) film 6 is suppressed, which will be described later.

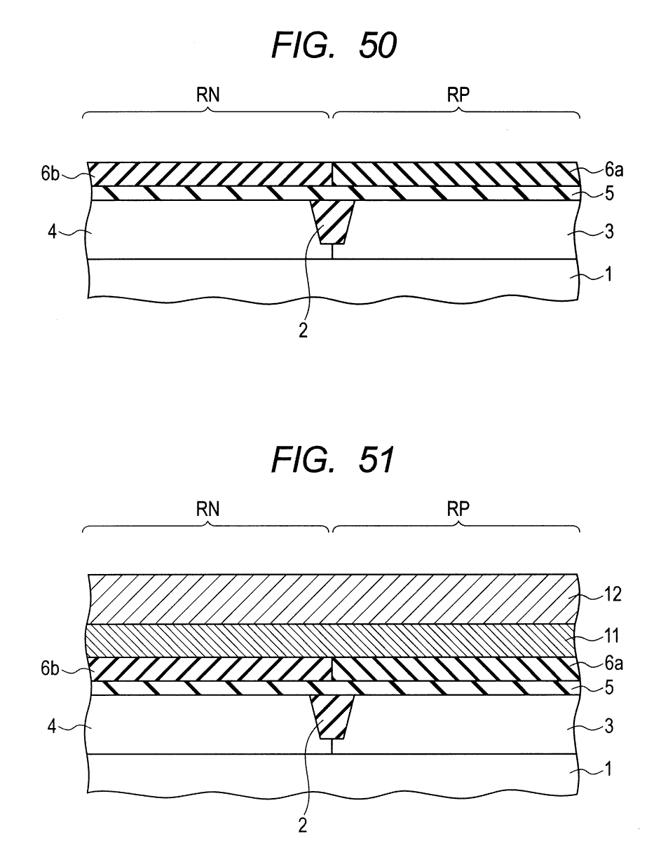

Next, by performing, e.g., a wet etching treatment or the like, a surplus of the lanthanum oxide (LaO) film 10 located in the element formation regions RP and RN is removed. By further performing a wet etching treatment or the like, the hard mask 8a located in the element formation region RP is removed. In this manner, as shown in FIG. 50, in the element formation region RN, the surface of the hafnium lanthanum oxynitride (HfLaON) film 6b is exposed. In the element formation region RP, the surface of the hafnium aluminum titanium oxynitride (HfAlTiON) film 6a is exposed.

Next, as shown in FIG. 51, the titanium nitride (TiN) film 11 is formed as the metal gate electrode material so as to come in contact with the respective surfaces of the hafnium lanthanum oxynitride (HfLaON) film 6b and the hafnium aluminum titanium oxynitride (HfAlTiON) film 6a. The polysilicon film 12 is formed so as to come in contact with the surface of the titanium nitride (TiN) film 11.

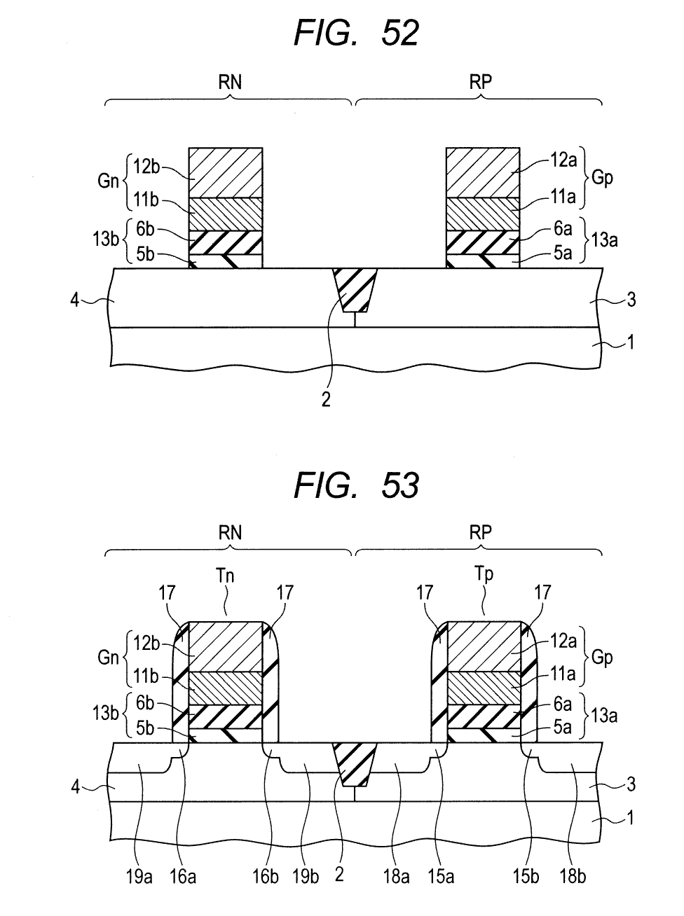

Next, through the same step as the step shown in FIG. 12, as shown in FIG. 52, in the element formation region RP, the gate electrode Gp is formed over the surface of the n-type well 3 via the gate insulating film 13a. In the element formation region RN, the gate electrode Gn is formed over the surface of the p-type well 4 via the gate insulating film 13b. The gate insulating film 13a is formed of the interface layer 5a and the hafnium aluminum titanium oxynitride (HfAlTiON) film 6a, while the gate insulating film 13b is formed of the interface layer 5b and the hafnium lanthanum oxynitride (HfLaON) film 6b. The gate electrode Gp is formed of the titanium nitride (TiN) film 11a and the polysilicon film 12a, while the gate electrode Gn is formed of the titanium nitride (TiN) film 11b and the polysilicon film 12b.

Next, through the same step as the step shown in FIG. 13, as shown in FIG. 53, in the n-type well 3, the p-type impurity regions 15a and 15b are formed as the LDD regions each at a predetermined depth from the surface thereof, and the p-type impurity regions 18a and 18b are formed as the source/drain regions each at a predetermined depth from the surface thereof. In the p-type well 4, the n-type impurity regions 16a and 16b are formed as the LDD regions each at a predetermined depth from the surface thereof, and the n-type impurity regions 19a and 19b are formed as the source/drain regions each at a predetermined depth from the surface thereof.

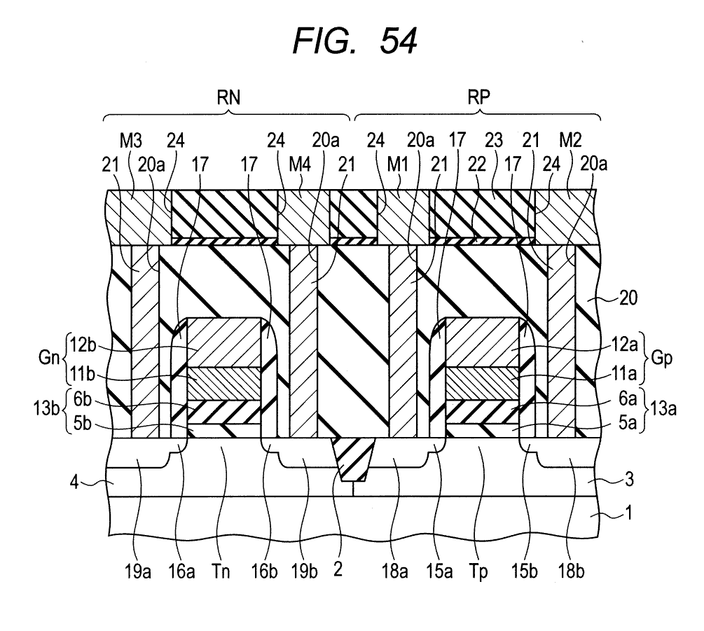

Next, through the same step as the step shown in FIG. 14, as shown in FIG. 54, the interconnects M1 and M2 electrically coupled to the p-type impurity regions 18a and 18b of the p-channel field effect transistor Tp via the plugs 21 and the like are formed. Also, the interconnects M3 and M4 electrically coupled to the n-type impurity regions 19a and 19b of the n-channel field effect transistor Tn via the plugs 21 and the like are formed. In this manner, the main portion of the semiconductor device is formed.

In the semiconductor device described above, the titanium nitride (TiN) film having the predetermined composition ratio R is used properly as the hard mask to suppress the diffusion of nitrogen into the hafnium oxynitride (HfON) film, and allow a desired characteristic to be obtained from the p-channel field effect transistor. A description will be given thereof. While evaluating the hard mask formed of the titanium nitride (TiN) film as part of development, the present inventors have found that there is a correlation between the composition ratio R of nitrogen (N) to titanium (Ti) and a work function.

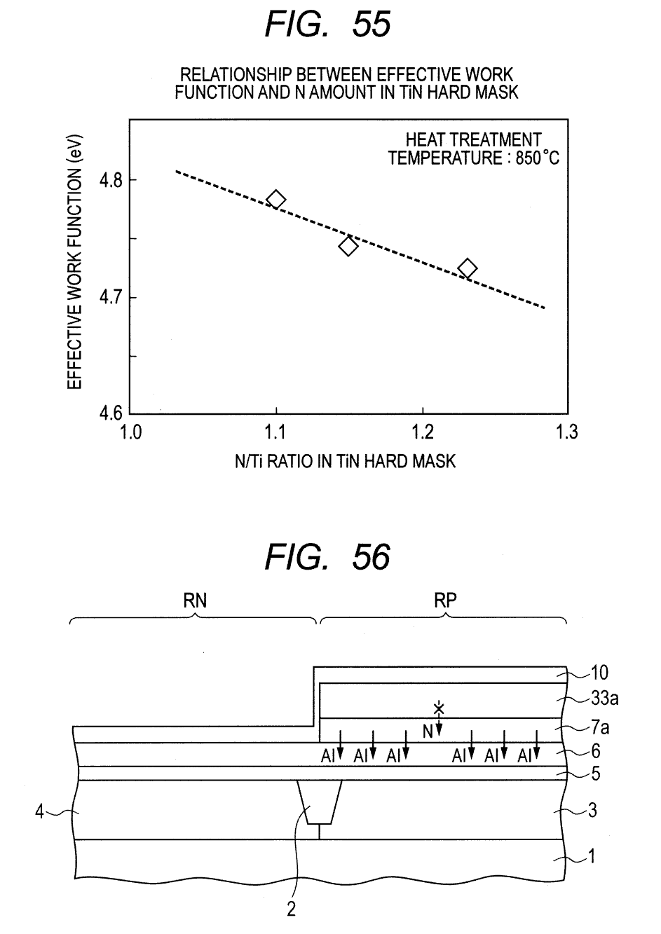

FIG. 55 is a graph showing the result thereof, which shows the relationship between the composition ratio R (N/Ti) of nitrogen (N) to titanium (Ti) when the contents of aluminum (Al) in the gate insulating films are assumed to be substantially the same and the work function of the p-channel field effect transistor. As shown in FIG. 55, as the value of the composition ratio R increases, the work function gradually decreases.

As already described, to reduce the threshold voltage of the p-channel field effect transistor for lower power consumption, the work function needs to be increased. To satisfy the need, the composition ratio R (N/Ti) preferably does not exceed 1.1. On the other hand, when the composition ratio R (N/Ti) is less than 1, titanium (Ti) is likely to be oxidized during the heat treatment to allow easy permeation of oxygen, resulting in an increased equivalent oxide thickness. Accordingly, the composition ratio R (N/Ti) is preferably not less than 1. Therefore, the composition ratio R (N/Ti) of the hard mask formed of the titanium nitride (TiN) film preferably satisfies 1≦R≦1.1.

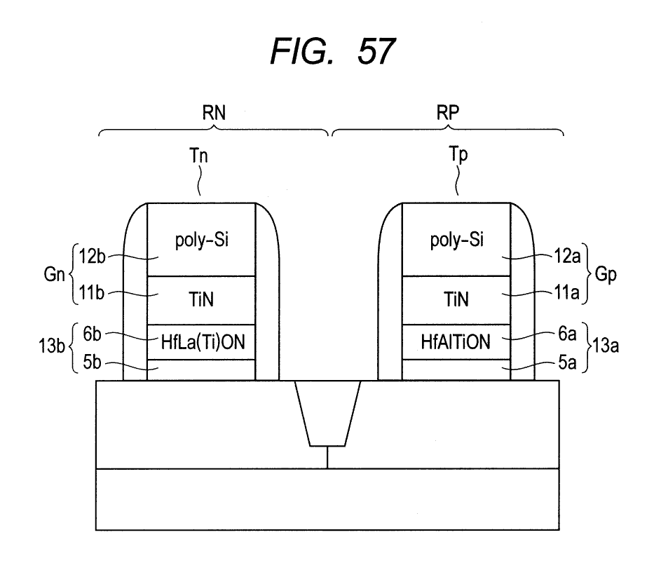

In the semiconductor device described above, as shown in FIG. 56, in the element formation region RP, aluminum (Al) in the aluminum (Al) film 7a is diffused toward the hafnium oxynitride (HfON) film 6, and thereby added thereto. In the hard mask 33a formed of the titanium nitride (TiN) film, the composition ratio R (N/Ti) is within the predetermined range (1≦R≦1.1) to suppress the amount of nitrogen (N) diffused from the hard mask 33a toward the hafnium oxynitride (HfON) film 6. This allows a reduction in the threshold voltage of the p-channel field effect transistor.

In addition, when the heat treatment is performed, titanium (Ti) in the hard mask 33a is also diffused into the hafnium oxynitride (HfON) film 6 through the aluminum (Al) film 7a. As a result, to the hafnium oxynitride (HfON) film 6, titanium (Ti) is also added as an element besides aluminum (Al) to form the hafnium aluminum titanium oxynitride (HfAlTiON) film 6a. As a result, the equivalent oxide thickness of the gate insulating film (High-k film) that has been increased by the addition of aluminum (Al) can be reduced by adding titanium (Ti) thereto. Therefore, a desired characteristic can be obtained from the p-channel field effect transistor.

On the other hand, in the element formation region RN, lanthanum (La) or lanthanum oxide (LaO) in the LaO film 10 is diffused into the hafnium oxynitride (HfON) film 6, and thereby added to the hafnium oxynitride (HfON) film 6.

In the semiconductor device thus formed, as shown in FIG. 57, the gate electrode of the p-channel field effect transistor Tp has a structure such that, over the hafnium aluminum titanium oxynitride (HfAlTiON) film 6a as a High-k film, the gate electrode Gp including the titanium nitride (TiN) film 11a and the polysilicon film 12a is stacked. On the other hand, the gate electrode of the n-channel field effect transistor Tn has a structure such that, over the hafnium lanthanum oxynitride (HfLaON) film 6b as a High-k film, the gate electrode Gn including the titanium nitride (TiN) film 11b and the polysilicon film 12b is stacked.

Note that, as described above, the case may also be assumed where, by the heat treatment after the titanium nitride (TiN) film serving as each of the gate electrodes is formed, titanium (Ti) in the titanium nitride film is diffused into a hafnium aluminum lanthanum oxynitride (HfAlLaON) film 6c. In the hafnium lanthanum oxynitride (HfLaON) film 6b of the n-channel field effect transistor shown in FIG. 57, “Ti” is shown by assuming the case where Ti is added through such diffusion.

The embodiments disclosed herein are illustrative, and the present invention is not limited thereto. The present invention is not defined by the scope described above, but rather by the claims and is intended to include the meanings equivalent to the claims and all the modifications within the claims.

The present invention is effectively used for a semiconductor device including complementary field effect transistors.

What is claimed is:

1. A semiconductor device including complementary field effect transistors, comprising:
a first element formation region for a p-channel field effect transistor which is formed in a main surface of a semiconductor substrate;
a second element formation region for an n-channel field effect transistor which is formed in the main surface of the semiconductor substrate;
a first gate insulating film formed so as to come in contact with a surface of the first element formation region;
a first gate electrode formed so as to come in contact with a surface of the first gate insulating film;
a second gate insulating film formed so as to come in contact with a surface of the second element formation region; and
a second gate electrode formed so as to come in contact with a surface of the second gate insulating film,
wherein the first gate insulating film is a hafnium aluminum titanium oxynitride (HfAlTiON) film obtained by adding aluminum (Al) and titanium (Ti) as elements to a hafnium oxynitride (HfON) film, and
wherein the second gate insulating film is a hafnium lanthanum oxynitride (HfLaON) film obtained by adding lanthanum (La) as an element to the hafnium oxynitride (HfON) film.

2. A semiconductor device according to claim 1,
wherein the second gate insulating film is a hafnium aluminum lanthanum oxynitride (HfAlLaON) film containing aluminum (Al) further added thereto as an element.

3. A semiconductor device according to claim 2,
wherein the second gate insulating film further contains titanium (Ti) as an element.

4. A semiconductor device according to claim 1,
wherein the first gate electrode includes a first titanium nitride (TiN) film formed so as to come in contact with the surface of the first gate insulating film, and a first polysilicon film formed so as to come in contact with a surface of the first titanium nitride (TiN) film, and
wherein the second gate electrode includes a second titanium nitride (TiN) film formed so as to come in contact with the surface of the second gate insulating film, and a second polysilicon film formed so as to come in contact with a surface of the second titanium nitride (TiN) film.

5. A method of manufacturing a semiconductor device including complementary field effect transistors, comprising the steps of:
forming, in a main surface of a semiconductor substrate, a first element formation region for a p-channel field effect transistor and a second element formation region for an n-channel field effect transistor;
forming a hafnium oxynitride (HfON) film such that the hafnium oxynitride (HfON) film comes in contact with respective surfaces of the first element formation region and the second element formation region;
forming a first-predetermined-element containing film containing aluminum (Al) as a predetermined element for controlling a threshold voltage of the p-channel field effect transistor such that the first-predetermined-element containing film comes in contact with a surface of the hafnium oxynitride (HfON) film;
forming a hard mask containing aluminum (Al) as a predetermined element for controlling the threshold voltage of the p-channel field effect transistor into a configuration in which the hard mask exposes a portion of the first-predetermined-element containing film located in the second element formation region, and covers a portion of the first-predetermined-element containing film located in the first element formation region;
performing processing using the hard mask as a mask to expose a portion of the hafnium oxynitride (HfON) film located in the second element formation region;
forming a second-predetermined-element containing film containing lanthanum (La) as a predetermined element for controlling a threshold voltage of the n-channel field effect transistor such that the second-predetermined-element containing film covers the portion of the hafnium oxynitride (HfON) film exposed in the second element formation region and the hard mask;
performing a heat treatment so as to add aluminum (Al) from the first-predetermined-element containing film to the hafnium oxynitride (HfON) film to form a first insulating film in the first element formation region, and add lanthanum (La) from the second-predetermined-element containing film to the hafnium oxynitride (HfON) film to form a second insulating film in the second element formation region;
forming a predetermined metal film such that the metal film comes in contact with respective surfaces of the first insulating film and the second insulating film;
forming a polysilicon film such that the polysilicon film comes in contact with a surface of the metal film; and
performing predetermined patterning on the polysilicon film, the metal film, the first insulating film, and the second insulating film to form a first gate electrode over the surface of the first element formation region via a first gate insulating film in the first element formation region, and form a second gate electrode over the surface of the second element formation region via a second gate insulating film in the second element formation region.

6. A method of manufacturing the semiconductor device according to claim 5,
wherein the first-predetermined-element containing film is an aluminum (Al) film.

7. A method of manufacturing the semiconductor device according to claim 5,
wherein the first-predetermined-element containing film is an aluminum oxide (AlO) film.

8. A method of manufacturing the semiconductor device according to claim 5,
wherein the second-predetermined-element containing film is a lanthanum oxide (LaO) film.

9. A method of manufacturing the semiconductor device according to claim 5,
wherein the hard film is a titanium aluminum nitride (TiAlN) film.

10. A method of manufacturing a semiconductor device including complementary field effect transistors, comprising the steps of:
forming, in a main surface of a semiconductor substrate, a first element formation region for a p-channel field effect transistor and a second element formation region for an n-channel field effect transistor;
forming a hafnium oxynitride (HfON) film such that the hafnium oxynitride (HfON) film comes in contact with respective surfaces of the first element formation region and the second element formation region;
forming a hard mask containing aluminum (Al) as a predetermined element for controlling a threshold voltage of the p-channel field effect transistor into a configuration in which the hard mask exposes a portion of the hafnium oxynitride (HfON) film located in the second element formation region, and covers a portion of the hafnium oxynitride (HfON) film located in the first element formation region;
forming a predetermined-element containing film containing lanthanum (La) as a predetermined element for controlling a threshold voltage of the n-channel field effect transistor such that the predetermined-element containing film covers the portion of the hafnium oxynitride (HfON) film exposed in the second element formation region and the hard mask;
performing a heat treatment so as to add aluminum (Al) from the hard mask to the hafnium oxynitride (HfON) film to form a first insulating film in the first element formation region, and add lanthanum (La) from the predetermined-element containing film to the hafnium oxynitride (HfON) film to form a second insulating film in the second element formation region;
forming a predetermined metal film such that the metal film comes in contact with respective surfaces of the first insulating film and the second insulating film;
forming a polysilicon film such that the polysilicon film comes in contact with a surface of the metal film; and
performing predetermined patterning on the polysilicon film, the metal film, the first insulating film, and the second insulating film to form a first gate electrode over the surface of the first element formation region via a first gate insulating film in the first element formation region, and form a second gate electrode over the surface of the second element formation region via a second gate insulating film in the second element formation region.

11. A method of manufacturing the semiconductor device according to claim 10,
wherein the hard mask is a titanium aluminum nitride (TiAlN) film.

12. A method of manufacturing the semiconductor device according to claim 10 or 11,
wherein the predetermined-element containing film is a lanthanum oxide (LaO) film.

13. A method of manufacturing a semiconductor device including complementary field effect transistors, comprising the steps of:
forming, in a main surface of a semiconductor substrate, a first element formation region for a p-channel field effect transistor and a second element formation region for an n-channel field effect transistor;
forming a hafnium oxynitride (HfON) film such that the hafnium oxynitride (HfON) film comes in contact with respective surfaces of the first element formation region and the second element formation region;
forming a first-predetermined-element containing film containing aluminum (Al) as a predetermined element for controlling a threshold voltage of the p-channel field effect transistor such that the first-predetermined-element containing film comes in contact with a surface of the hafnium oxynitride (HfON) film;
forming a hard mask formed of a titanium nitride (TiN) film containing titanium (Ti) and nitrogen (N) as elements at a predetermined composition ratio R such that the hard mask covers a portion of the first-predetermined-element containing film located in the first element formation region;
performing processing using the hard mask as a mask to expose a portion of the hafnium oxynitride (HfON) film located in the second element formation region;
forming a second-predetermined-element containing film containing lanthanum (La) as a predetermined element for controlling a threshold voltage of the n-channel field effect transistor such that the second-predetermined-element containing film covers the portion of the hafnium oxynitride (HfON) film exposed in the second element formation region and the hard mask;
performing a heat treatment so as to add aluminum (Al) from the first-predetermined-element containing film to the hafnium oxynitride (HfON) film to form a first insulating film in the first element formation region, and add lanthanum (La) from the second-predetermined-element containing film to the hafnium oxynitride (HfON) film to form a second insulating film in the second element formation region;
forming a predetermined metal film such that the metal film comes in contact with respective surfaces of the first insulating film and the second insulating film;
forming a polysilicon film such that the polysilicon film comes in contact with a surface of the metal film; and
performing predetermined patterning on the polysilicon film, the metal film, the first insulating film, and the second insulating film to form a first gate electrode over the surface of the first element formation region via a first gate insulating film in the first element formation region, and form a second gate electrode over the surface of the second element formation region via a second gate insulating film in the second element formation region,
wherein, in the step of forming the hard mask, the hard mask is formed such that the composition ratio R satisfies 1≦R≦1.1.

14. A method of manufacturing the semiconductor device according to claim 13,
wherein the first-predetermined-element containing film is an aluminum (Al) film.

15. A method of manufacturing the semiconductor device according to claim 13 or 14,
wherein the second-predetermined-element containing film is a lanthanum oxide (LaO) film.
